(19) United States
(12) Patent Application Publication
(10) Pub. No.: US 2025/0169212 A1
(43) Pub. Date: May 22, 2025

(54) LIGHT DETECTION DEVICE AND ELECTRONIC DEVICE

(71) Applicant: SONY SEMICONDUCTOR SOLUTIONS CORPORATION, Kanagawa (JP)

(72) Inventors: Atsushi TODA, Kanagawa (JP); Shinichiro NOUDO, Kanagawa (JP); Katsuji KIMURA, Kanagawa (JP); Naoto SASAKI, Kanagawa (JP)

(73) Assignee: SONY SEMICONDUCTOR SOLUTIONS CORPORATION, Kanagawa (JP)

(21) Appl. No.: 18/840,995

(22) PCT Filed: Feb. 20, 2023
(86) PCT No.: PCT/JP2023/005896

§ 371 Date: Aug. 23, 2024

(30) Foreign Application Priority Data
Mar. 1, 2022 (JP) 2022-031055

(51) Int. Cl. H10F 39/00; G02B 5/20; H10F 39/18

(52) U.S. Cl. CPC H10F 39/805; G02B 5/208; H10F 39/024; H10F 39/182; H10F 39/806

(57) ABSTRACT

Provided is a light detection device in which deterioration in color reproducibility is suppressed. The light detection device includes a multilayer filter having a stacked structure in which a high-refractive-index layer and a low-refractive-index layer are alternately stacked, and having a transmission spectrum specific to the stacked structure; and a semiconductor layer that allows light having passed through the multilayer filter to enter therein and has a plurality of photoelectric conversion regions arranged in a two-dimensional array. The multilayer filter as a whole is convexly curved toward the semiconductor layer.

### TECHNICAL FIELD

The present technology (technology according to the present disclosure) relates to a light detection device and an electronic device, and particularly relates to a light detection device and an electronic device having a multilayer filter.

### BACKGROUND ART

When an image sensor detects a large amount of near-infrared light (infrared rays) that is invisible to the human eye, the color reproduction of the obtained image will deviate from that when the subject is viewed directly with the human eye. Therefore, a filter such as an infrared-cut filter is provided in the image sensor to reduce the amount of near-infrared light detected by the image sensor. For example, in PTL 1, a plurality of multilayer films having different refractive indices are provided on the surface of the sealing glass on the optical sensor side.

### CITATION LIST

### Patent Literature

PTL 1: JP 2013-41941A

### SUMMARY

### Technical Problem

At a position on the image plane where the image height is high, the principal ray obliquely enters the multilayer filter. When the principal ray enters the multilayer filter obliquely, color reproducibility may deteriorate. The present technology aims to provide a light detection device and an electronic device in which deterioration in color reproducibility is suppressed.

### Solution to Problem

A light detection device according to one aspect of the present technology includes a multilayer filter having a stacked structure in which a high-refractive-index layer and a low-refractive-index layer are alternately stacked, and having a transmission spectrum specific to the stacked structure; and a semiconductor layer that allows light having passed through the multilayer filter to enter therein and has a plurality of photoelectric conversion regions arranged in a two-dimensional array, wherein the multilayer filter as a whole is convexly curved toward the semiconductor layer.

A light detection device according to another aspect of the present technology includes an optical element having a plurality of structures arranged at intervals in a width direction in plan view; a multilayer filter that allows light having passed through the optical element to enter therein, has a stacked structure in which a high-refractive-index layer and a low-refractive-index layer are alternately stacked, and has a transmission spectrum specific to the stacked structure; and a semiconductor layer having a light-receiving region formed by arranging a plurality of photoelectric conversion regions in a two-dimensional array on which light having passed through the multilayer filter can be incident, wherein the optical element is provided, for each photoelectric conversion region, at a position overlapping the photoelectric conversion region in plan view, in a first optical element that is one of the optical elements arranged so as to overlap a position away from a center of the light-receiving region in plan view, the structures are arranged at least along a direction from a portion of the first optical element near an edge of the light-receiving region to a portion near the center, and a density of the structures in the first optical element in plan view is higher in the portion of the first optical element near the center of the light-receiving region than in the portion near the edge.

An electronic device according to one aspect of the present technology includes the light detection device and an optical system that forms an image of image light from a subject on the light detection device.

### BRIEF DESCRIPTION OF DRAWINGS

FIG. 1 is a chip layout diagram showing a configuration example of a light detection device according to a first embodiment of the present technology.

FIG. 2 is a block diagram showing a configuration example of the light detection device according to the first embodiment of the present technology.

FIG. 3 is an equivalent circuit diagram of a pixel of the light detection device according to the first embodiment of the present technology.

FIG. 4A is a longitudinal cross-sectional view of the light detection device according to the first embodiment of the present technology.

FIG. 4B is a longitudinal cross-sectional view of the light detection device according to the first embodiment of the present technology.

FIG. 4C is a longitudinal cross-sectional view of a multilayer filter included in the light detection device according to the first embodiment of the present technology.

FIG. 4D is an explanatory diagram showing the relationship between the light detection device and the principal ray according to the first embodiment of the present technology.

FIG. 4E is an explanatory diagram showing the relationship between a multilayer filter and the diffracted reflected light generated by the light detection device according to the first embodiment of the present technology.

FIG. 5A is a process cross-sectional view showing a method of manufacturing the light detection device according to the first embodiment of the present technology.

FIG. 5B is a process cross-sectional view subsequent to FIG. 5A.

FIG. 6 is an explanatory diagram showing the relationship between a multilayer filter and the diffracted reflected light generated in a conventional light detection device.

FIG. 7 is an explanatory diagram showing the relationship between a conventional light detection device and a principal ray.

FIG. 8 is an explanatory diagram illustrating shortening of the cutoff wavelength of a multilayer filter.

FIG. 9 is an explanatory diagram illustrating shortening of the cutoff wavelength of a multilayer filter.

FIG. 10 is a longitudinal cross-sectional view of a light detection device according to Modified Example 2 of the first embodiment of the present technology.

FIG. 11 is a longitudinal cross-sectional view of a light detection device according to Modified Example 3 of the first embodiment of the present technology.

FIG. 12 is a longitudinal cross-sectional view of a light detection device according to Modified Example 4 of the first embodiment of the present technology.

FIG. 13 is a longitudinal cross-sectional view of a light detection device according to Modified Example 5 of the first embodiment of the present technology.

FIG. 14A is a process cross-sectional view showing a method of manufacturing the light detection device according to Modified Example 5 of the first embodiment of the present technology.

FIG. 14B is a process cross-sectional view subsequent to FIG. 14A.

FIG. 14C is a process cross-sectional view subsequent to FIG. 14B.

FIG. 15A is a process cross-sectional view showing a method of manufacturing a light detection device according to Modified Example 6 of the first embodiment of the present technology.

FIG. 15B is a process cross-sectional view subsequent to FIG. 15A.

FIG. 16 is a longitudinal cross-sectional view of a light detection device according to Modified Example 7 of the first embodiment of the present technology.

FIG. 17A is a process cross-sectional view showing a method of manufacturing the light detection device according to Modified Example 7 of the first embodiment of the present technology.

FIG. 17B is a process cross-sectional view subsequent to FIG. 17A.

FIG. 18A is a chip layout diagram showing a configuration example of a light detection device according to a second embodiment of the present technology.

FIG. 18B is a longitudinal cross-sectional view of the light detection device according to the second embodiment of the present technology.

FIG. 18C is a plan view of an optical element layer and an optical element included in the light detection device according to the second embodiment of the present technology.

FIG. 19A is an enlarged plan view showing an optical element included in the light detection device according to the second embodiment of the present technology.

FIG. 19B is a longitudinal cross-sectional view showing an enlarged view of an optical element included in the light detection device according to the second embodiment of the present technology.

FIG. 19C is a longitudinal cross-sectional view showing an enlarged view of an optical element included in the light detection device according to the second embodiment of the present technology.

FIG. 20 is a longitudinal cross-sectional view of a multilayer filter included in the light detection device according to the second embodiment of the present technology.

FIG. 21 is a plan view of an optical element layer and an optical element included in a light detection device according to Modified Example 1 of the second embodiment of the present technology.

FIG. 22 is a plan view of an optical element layer and an optical element included in a light detection device according to Modified Example 2 of the second embodiment of the present technology.

FIG. 23 is a longitudinal cross-sectional view of a multilayer filter included in a light detection device according to Modified Example 3 of the second embodiment of the present technology.

FIG. 24 is a longitudinal cross-sectional view of a multilayer filter included in a light detection device according to Modified Example 4 of the second embodiment of the present technology.

FIG. 25 is an explanatory diagram showing spectral characteristics of a multilayer filter included in the light detection device according to the second embodiment, Modified Example 3 of the second embodiment, and Modified Example 4 of the second embodiment of the present technology.

FIG. 26 is a plan view of an optical element included in a light detection device according to Modified Example 5 of the second embodiment of the present technology.

FIG. 27 is a block diagram showing an example of a schematic configuration of an electronic device.

FIG. 28 is a block diagram showing an exemplary schematic configuration of a vehicle control system.

FIG. 29 is an explanatory diagram showing an example of the installation positions of vehicle external information detection units and imaging units.

FIG. 30 shows a schematic configuration example of an endoscopic surgery system.

FIG. 31 is a block diagram showing an example of the functional configuration of a camera head and a CCU.

### DESCRIPTION OF EMBODIMENTS

Hereinafter, preferable embodiments for implementing the present technology will be described with reference to the drawings. The embodiments which will be described below show examples of representative embodiments of the present technology, and the scope of the present technology should not be narrowly interpreted on the basis of this.

In the illustration of the drawings, the same or similar portions are denoted with the same or similar reference signs. However, it should be noted that the drawings are schematic, and the relationship between thicknesses and planar dimensions, the ratio between thicknesses of respective layers, and the like, may be different from actual ones. Therefore, specific thicknesses and dimensions should be determined by considering the following descriptions. In addition, it goes without saying that the drawings include parts where dimensional relationships and ratios are different from each other between the drawings.

The embodiments described below illustrate devices and methods for embodying the technical ideas of the present technology, and the technical ideas of the present technology do not limit the material, shape, structure, arrangement, and the like of the components to the embodiments described below. The technical ideas of the present technology can be variously modified within the technical scope described in the claims.

Description will be given in the following order.
1. First Embodiment
2. Second Embodiment
3. Third Embodiment
Example of application to electronic device
Example of application to mobile object
Application example to endoscopic surgery system

### First Embodiment

In the first embodiment, an example in which the present technology is applied to a light detection device that is a back-illuminated CMOS (Complementary Metal Oxide Semiconductor) image sensor will be described.

### <<Overall Configuration of Light Detection Device>>

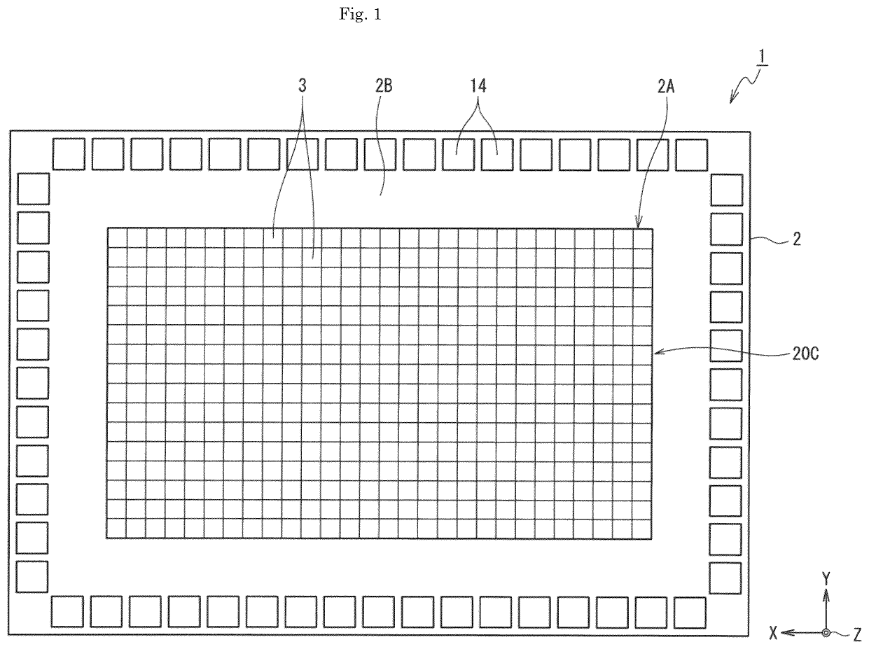

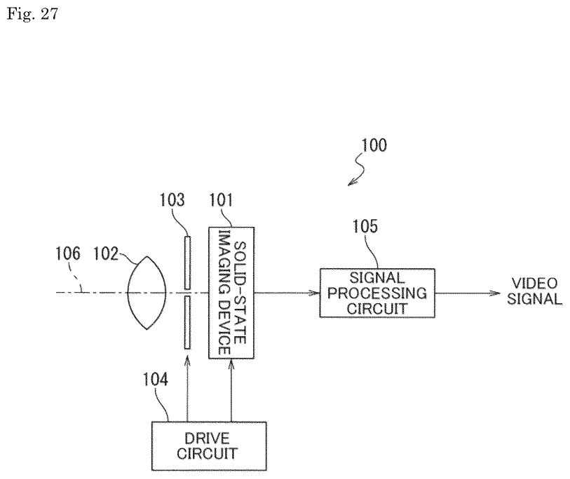

First, an overall configuration of a light detection device 1 will be explained. As shown in FIG. 1, the light detection device 1 according to a first embodiment of the present technology is mainly configured with a semiconductor chip 2 having a rectangular two-dimensional planar shape in plan view. That is, the light detection device 1 is mounted on the semiconductor chip 2. As shown in FIG. 27, this light detection device 1 captures image light (incident light 106) from a subject through an optical lens (optical system) 102, and converts the light intensity of incident light 106 formed on an imaging surface into an electrical signal for each pixel and output the electrical signal as a pixel signal.

As shown in FIG. 1, the semiconductor chip 2 in which the light detection device 1 is mounted has a pixel region 2A of a rectangular shape disposed in a center part and a peripheral region 2B disposed on an outer side of this pixel region 2A to surround the pixel region 2A on a two-dimensional plane including an X direction and a Y direction intersecting each other. In addition, a region of a semiconductor layer 20, which will be described later, that overlaps the pixel region 2A in plan view is referred to as a light-receiving region 20C to distinguish it from other regions.

The pixel region 2A is a light-receiving surface that receives light collected by the optical lens 102 shown in FIG. 27, for example. In the pixel region 2A, a plurality of pixels 3 are arranged in a matrix on a two-dimensional plane including the X and Y directions. In other words, the pixels 3 are repeatedly arranged in each of the X and Y directions that intersect each other within a two-dimensional plane. In addition, in the present embodiment, the X and Y directions are perpendicular to each other, for example. Further, the direction perpendicular to both the X and Y directions is the Z direction (thickness direction, stacking direction). The direction perpendicular to the Z direction is the horizontal direction.

As shown in FIG. 1, a plurality of bonding pads 14 are disposed in the peripheral region 2B. The plurality of bonding pads 14 are arranged, for example, along each of the four sides of the two-dimensional plane of the semiconductor chip 2. Each of the plurality of bonding pads 14 is an input/output terminal used when the semiconductor chip 2 is electrically connected to an external device.

### <Logic Circuit>

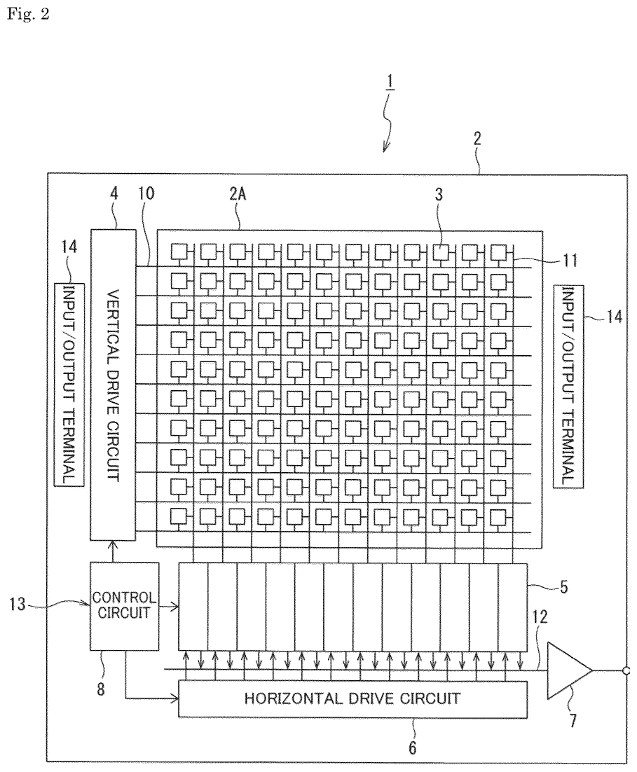

As shown in FIG. 2, the semiconductor chip 2 includes a logic circuit 13 that includes, a vertical drive circuit 4, a column signal processing circuit 5, a horizontal drive circuit 6, an output circuit 7, a control circuit 8, and the like. The logic circuit 13, for example, is configured by Complementary MOS (CMOS) circuits having Metal Oxide Semiconductor Field Effect Transistors (MOSFET) of an n-channel conduction type and MOSFETs of a p-channel conduction type as field effect transistors.

For example, the vertical drive circuit 4 is constituted of a shift register. The vertical drive circuit 4 sequentially selects a desired pixel drive line 10, supplies a pulse for driving the pixels 3 to the selected pixel drive line 10, and drives respective pixels 3 in units of rows. In other words, the vertical drive circuit 4 sequentially performs selective scanning of the pixels 3 of the pixel region 2A in units of rows in a vertical direction and supplies a pixel signal from the pixel 3 based on signal electric charge generated in accordance with a received light quantity by the photoelectric conversion element of each pixel 3 to the column signal processing circuit 5 through a vertical signal line 11.

The column signal processing circuit 5, for example, is disposed in each column of the pixels 3 and performs signal processing such as noise elimination or the like for each pixel column on signals output from the pixels 3 corresponding to one row. For example, the column signal processing circuit 5 performs signal processing such as Correlated Double Sampling (CDS) for eliminating a pixel-specific fixed pattern noise, Analog Digital (AD) conversion, and the like. A horizontal selection switch (not shown) is connected and disposed between an output storage of the column signal processing circuit 5 and the horizontal signal line 12.

For example, the horizontal drive circuit 6 is constituted of a shift register. The horizontal drive circuit 6 sequentially selects each column signal processing circuit 5 by sequentially outputting a horizontal scanning pulse to the column signal processing circuit 5, and outputs a pixel signal on which signal processing has been performed from each column signal processing circuit 5 to a horizontal signal line 12.

The output circuit 7 performs signal processing on the pixel signals sequentially supplied from the respective column signal processing circuits 5 through the horizontal signal line 12, and outputs the resulting pixel signals. Examples of the signal processing which may be used include buffering, black level adjustment, column variation correction, various types of digital signal processing, and the like, for example.

The control circuit 8 generates a clock signal or a control signal as a reference for operations of the vertical drive circuit 4, the column signal processing circuit 5, the horizontal drive circuit 6, and the like based on a vertical synchronization signal, a horizontal synchronization signal, and a master clock signal. In addition, the control circuit 8 outputs the generated clock signal or control signal to the vertical drive circuit 4, the column signal processing circuit 5, the horizontal drive circuit 6, and the like.

### <Pixel>

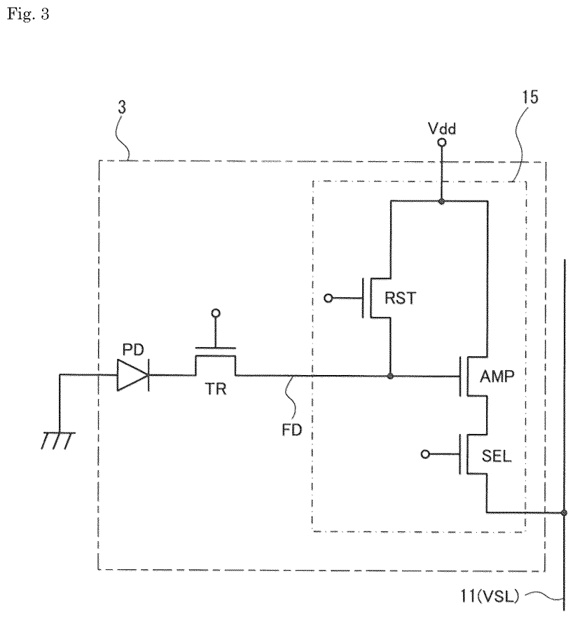

FIG. 3 is an equivalent circuit diagram showing a configuration example of the pixel 3. The pixel 3 includes a photoelectric conversion element PD, a charge accumulation region (Floating Diffusion) FD accumulating (holding) signal electric charge acquired through photoelectric conversion using this photoelectric conversion element PD, and a transfer transistor TR that transmits signal electric charge acquired through photoelectric conversion using this photoelectric conversion element PD to the charge accumulation region FD. In addition, the pixel 3 includes a readout circuit 15 that is electrically connected to the charge accumulation region FD.

The photoelectric conversion element PD generates signal electric charge corresponding to a light reception amount. In addition, the photoelectric conversion element PD temporarily accumulates (holds) the generated signal electric charge. The photoelectric conversion element PD has a cathode side electrically connected to a source region of the transfer transistor TR and an anode side electrically connected to a reference electric potential line (for example, the ground). As the photoelectric conversion element PD, for example, a photodiode is used.

A drain region of the transfer transistor TR is electrically connected to the charge accumulation region FD, a gate electrode of the transfer transistor TR is electrically connected to a transfer transistor drive line among pixel drive lines 10 (see FIG. 2).

The charge accumulation region FD temporarily accumulates and holds signal electric charge transmitted from the photoelectric conversion element PD through the transfer transistor TR.

The readout circuit 15 reads the signal charges accumulated in the charge accumulation region FD and outputs the pixel signals based on the signal charges. The readout circuit 15 includes, but is not limited to, an amplification transistor AMP, a selection transistor SEL, and a reset transistor RST as a pixel transistor. The transistor (AMP, SEL, or RST) is constituted by a MOSFET having a gate insulating film made of, for example, a silicon oxide film (a SiO₂ film), a gate electrode, and a pair of main electrode regions functioning as a source region and a drain region. The transistor may be a Metal Insulator Semiconductor FET (MISFET) whose gate insulating film is a silicon nitride film (a Si₃N₄ film) or a stacked film of the silicon nitride film and a silicon oxide film.

The amplification transistor AMP has a source region electrically connected to a drain region of the selection transistor SEL and a drain region electrically connected to a power source line Vdd and a drain region of the reset transistor. The gate electrode of the amplification transistor AMP is electrically connected to the charge accumulation region FD and a source region of the reset transistor RST.

In the selection transistor SEL, a source region is electrically connected to the vertical signal line 11 (VSL), and a drain is electrically connected to the source region of the amplification transistor AMP. A gate electrode of the selection transistor SEL is electrically connected to a selection transistor drive line among pixel drive lines 10 (see FIG. 2).

In the reset transistor RST, a source region is electrically connected to the charge accumulation region FD and the gate electrode of the amplification transistor AMP, and a drain region is electrically connected to the power source line Vdd and the drain region of the amplification transistor AMP. A gate electrode of the reset transistor RST is electrically connected to a reset transistor drive line among the pixel drive lines 10 (see FIG. 2).

### <<Specific Configuration of Light Detection Device>>

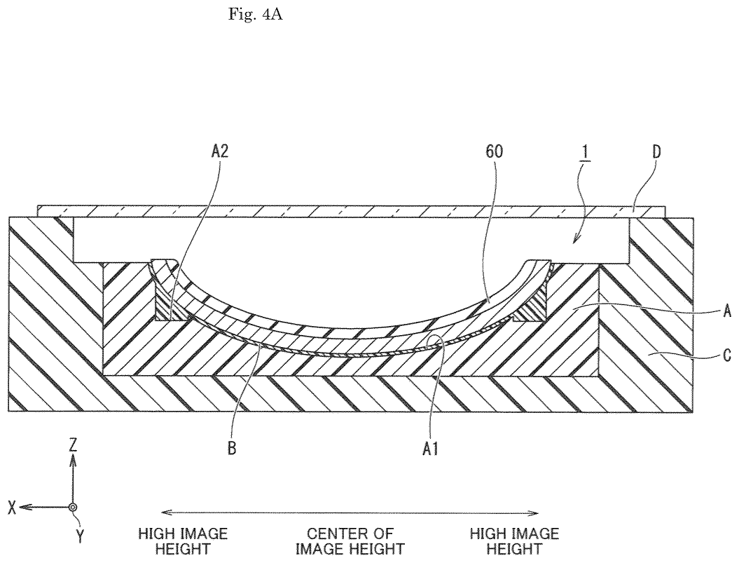

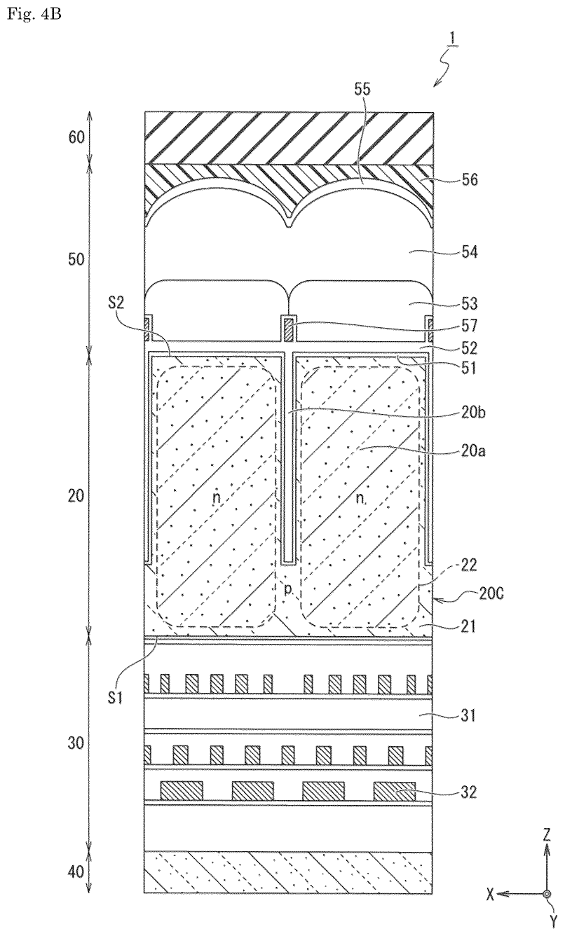

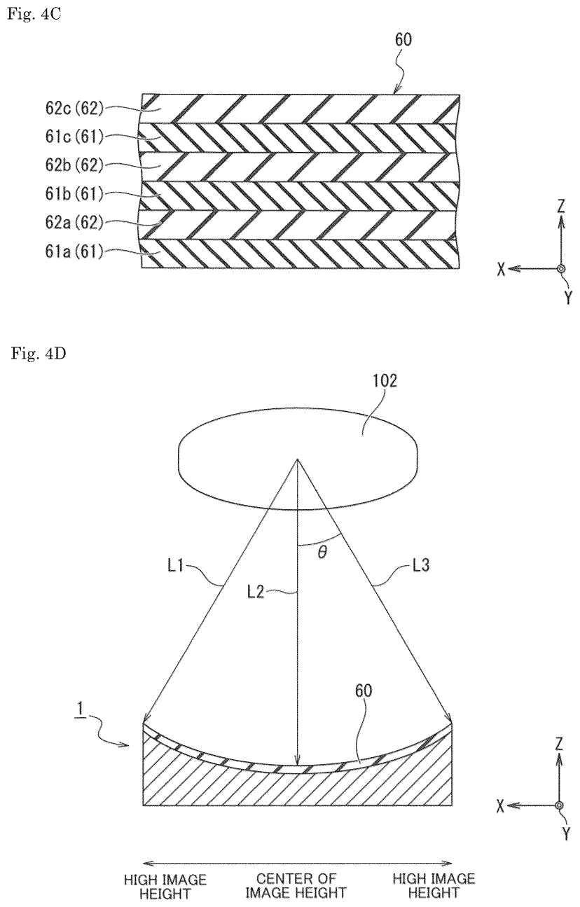

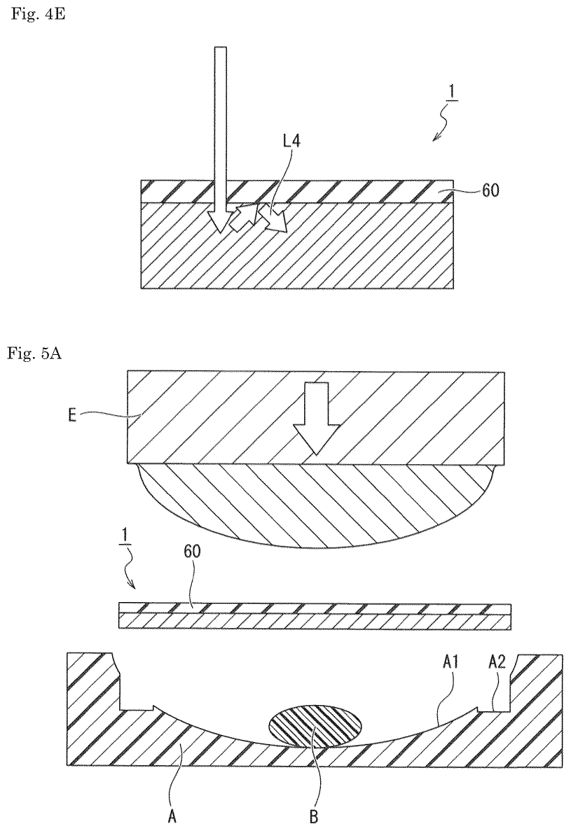

Next, a specific configuration of the light detection device 1 will be described using FIGS. 4A to 4E. First, a pedestal A shown in FIG. 4A will be explained.

### <Pedestal>

As shown in FIG. 4A, the light detection device 1 (semiconductor chip 2) is fixed to the pedestal A. More specifically, the surface of the light detection device 1 opposite to the light-receiving surface is fixed to the pedestal A via an adhesive B made of, for example, a resin material. The pedestal A has one surface A1 convexly curved toward the other surface, and has a groove A2 on one surface A1 side. The light detection device 1 is fixed to the pedestal A along one surface A1 of the pedestal A. Note that the device including the pedestal A may also be referred to as the light detection device 1. The light detection device 1 and the pedestal A are sealed, but not limited to, with a mold resin C and a sealing glass D, for example. The sealing glass D is provided so as to overlap the light-receiving surface side of the light detection device 1 in plan view.

As shown in FIG. 4A, since the light detection device 1 is fixed along the curved surface of the pedestal A, the light detection device 1 is also curved along the curved surface of the pedestal A. The light detection device 1 has a multilayer filter 60 on the light-receiving surface side. As shown in FIGS. 4A and 4D, the multilayer filter 60 as a whole is convexly curved toward the semiconductor layer 20, which will be described later. That is, the multilayer filter 60 as a whole is convexly curved toward the center (center of image height) of the light-receiving region 20C of the semiconductor layer 20. The multilayer filter 60 as a whole is curved concavely toward the optical lens 102. Note that although FIG. 4A shows a longitudinal cross-sectional structure when the light detection device 1 is cut along the X direction, even if the longitudinal cross-sectional structure is cut along other directions, the light detection device 1 has a similarly curved structure.

Even if the principal ray entering the multilayer filter 60 is oblique light, it is suppressed from entering the multilayer filter 60 at an angle far from vertical. For example, principal rays L1, L2, and L3 shown in FIG. 4D can all be incident at vertical or near-vertical angles. The principal ray L2 is light that travels along the Z direction, and is incident on a portion of the multilayer filter 60 that is stacked near the center (center of image height) of the light-receiving region 20C. The principal rays L1 and L3 are lights that travel obliquely with respect to the Z direction, and are incident on a portion of the multilayer filter 60 that is stacked near the edge of the light-receiving region 20C (position where the image height is high). In this way, the principal rays L1, L2, and L3 are all suppressed from entering the multilayer filter 60 at an angle far from vertical. The angle of incidence of the principal ray on the multilayer filter 60 is determined by the design of the optical lens 102. Therefore, the curved shape of the light detection device 1 may be designed in accordance with the design of the optical lens 102. For example, the curved shape of the light detection device 1 may be a shape that matches performance such as field curvature correction. The optical characteristics of the optical lens 102 may be designed to adapt to the curved shape of the light detection device 1. Note that the angle θ is the angle between the principal ray and the Z direction.

### <Stacked Structure of Light Detection Device>

FIG. 4B is a longitudinal cross-section showing the cross-sectional structure of some pixels 3 of the light detection device 1 shown in FIG. 4A. Note that FIGS. 4B, 4C, and 4E only show a part of the light detection device 1, so it does not appear to be curved, but the light detection device 1 as a whole is curved in the same manner as in FIG. 4A. The light detection device 1 (semiconductor chip 2) has a stacked structure in which the multilayer filter 60, a light-receiving-surface-side stacked body 50, the semiconductor layer 20, a wiring layer 30, and a support substrate 40 are stacked in this order. Note that in the drawings that follow, the illustration of the support substrate 40 may be omitted.

### <Multilayer Filter>

The multilayer filter 60 stacked on a planarization film 56 is provided so as to continuously cover at least the pixel region 2A without interruption. As already explained, the multilayer filter 60 as a whole is convexly curved toward the semiconductor layer 20, more specifically, toward the center (center of image height) of the light-receiving region 20C. The multilayer filter 60 has a stacked structure in which a high-refractive-index layer 61 and a low-refractive-index layer 62 are alternately stacked, and is a multilayer filter having a transmission spectrum specific to the stacked structure. More specifically, the multilayer filter 60 has a stacked structure in which a high-refractive-index layer 61a, a low-refractive-index layer 62a, a high-refractive-index layer 61b, a low-refractive-index layer 62b, a refractive index layer 61c, and a low-refractive-index layer 62c are stacked in this order, as shown in FIG. 4C, for example. Note that the numbers of high-refractive-index layers 61 and low-refractive-index layers 62 are not limited to the example shown in FIG. 4C. The number of stacked layers can be appropriately set depending on the performance required of the multilayer filter 60. Furthermore, when the layers of the high-refractive-index layers 61 are not distinguished from each other, they are simply referred to as the high-refractive-index layer 61. Similarly, when the layers of the low-refractive-index layers 62 are not distinguished from each other, they are simply referred to as the low-refractive-index layer 62. Each layer of the high-refractive-index layer 61 and the low-refractive-index layer 62 is provided so as to continuously cover at least the pixel region 2A without interruption. The multilayer filter 60 can constitute an infrared cut filter (IRCF) by appropriately combining materials and film thicknesses and stacking them. The present embodiment will be described assuming that the multilayer filter 60 is an infrared-cut filter. The multilayer filter 60 is a reflective infrared-cut filter, and is a filter that reflects at least most of the infrared rays.

Examples of the material constituting the high-refractive-index layer 61 include the following materials. As the material constituting the high-refractive-index layer 61, only one type may be used, or different materials may be used for different layers. Hereinafter, the refractive index may be expressed as “n”.

### Material/Refractive Index

$$Aluminum oxide ( {Al}_{2} {O}_{3} ) / n = 1.77$$

$$Silicon nitride ( SiN , {Si}_{3} {N}_{4} ) / n = 1.91$$

$$Hafnium oxide ( Hf {O}_{2} ) / n = 1.93$$

$$Zirconium oxide ( Zr {O}_{2} ) / n = 2 \text{.00}$$

$$Tantalum oxide ( {Ta}_{2} {O}_{5} ) / n = 2.15$$

$$Titanium oxide ( Ti {O}_{2} ) / n = 2.28$$

$$Niobium oxide ( {Nb}_{2} {O}_{5} ) / n = 2.33$$

In addition to the above materials, examples of materials constituting the high-refractive-index layer 61 include cerium oxide (CeO₂), zinc oxide (ZnO), indium oxide (In₂O₃), and tin oxide (SnO₂).

Examples of the material constituting the low-refractive-index layer 62 include the following materials. As the material constituting the low-refractive-index layer 62, only one type may be used, or different materials may be used for different layers.

### Material/Refractive Index

$$Silicon oxide ( Si {O}_{2} ) / n = 1.46$$

$$Carbon - containing silicon oxide ( Si O C ) / n = 1.4$$

$$Magnesium fluoride ( Mg {F}_{2} ) / n = 1.38$$

$$Aluminum fluoride ( Al {F}_{3} ) / n = 1.38$$

As shown in FIGS. 4B and 4E, the multilayer filter 60 is provided integrally with the light detection device 1. More specifically, the multilayer filter 60 is integrally stacked on the light detection device 1. In the present embodiment, the multilayer filter 60 is stacked on the side of the light-receiving-surface-side stacked body 50 opposite to the semiconductor layer 20 side. More specifically, the multilayer filter 60 is stacked on the side of an on-chip lens 54 (described later) opposite to the semiconductor layer 20 side, with the planarization film 56 (described later) interposed therebetween. That is, the multilayer filter 60 is provided upstream of the on-chip lens 54 in the light traveling direction. As shown in FIG. 4E, part of the light that has passed through the multilayer filter 60 is diffracted and reflected by a periodic structure (not shown) such as the on-chip lens 54 inside the light detection device 1. The diffracted and reflected light may be further reflected by the interface of the multilayer filter 60 and may enter the semiconductor layer 20 as shown in light L4 shown in FIG. 4E. The farther such light L4 is incident on a pixel from the pixel on which the principal ray is incident, the greater the flare of the image becomes. In the present embodiment, since the multilayer filter 60 is stacked on the outermost surface of the light detection device 1, it is possible to suppress the light L4 that causes flare from entering the pixel 3 located far away in plan view. In this way, it is possible to suppress the region where flare occurs from becoming wider.

### <Light-Receiving-Surface-Side Stacked Body>

As shown in FIG. 4B, the light-receiving-surface-side stacked body 50 has a stacked structure in which for example, but not limited to, a fixed charge film 51, an insulating film 52, a color filter 53, the on-chip lens 54, and the planarization film 56 are stacked in this order from the second surface S2 side of the semiconductor layer 20. The on-chip lens 54 has an anti-reflection film 55 on the side opposite to the semiconductor layer 20 to prevent reflection. The anti-reflection film 55 has a refractive index different from that of the main body portion of the on-chip lens 54. The light detection device 1 includes a light-shielding film 57 disposed closer to the semiconductor layer 20 than the on-chip lens 54 in the boundary region of the pixel 3.

The fixed charge film 51 has a negative fixed charge due to an oxygen dipole, and serves to strengthen pinning. The fixed charge film 51 may be made of, for example, an oxide or nitride containing at least one of hafnium (Hf), aluminum (Al), zirconium (Zr), tantalum (Ta), and titanium (Ti). The fixed charge film 51 can be formed by, for example, chemical vapor deposition (CVD), sputtering, or Atomic Layer Deposition (ALD). When ALD is employed, it is possible to simultaneously form a silicon oxide film that reduces the interface level while forming the fixed charge film 51, which is preferable. The fixed charge film 51 is made of an oxide or nitride containing at least one of lanthanum, cerium, neodymium, promethium, samarium, europium, gadolinium, terbium, dysprosium, holmium, thulium, ytterbium, lutetium, and yttrium. Furthermore, the fixed charge film 51 can also be made of a hafnium oxynitride or an aluminum oxynitride. Moreover, silicon or nitrogen can be added to the fixed charge film 51 such that the amount of silicon or nitrogen does not degrade insulation. In this way, the heat resistance and the like of the fixed charge film 51 can be improved. It is preferable that the fixed charge film 51 also have the role of an anti-reflection film for the silicon substrate having a high refractive index by controlling the film thickness or by stacking multiple layers.

The insulating film 52 is provided between the color filter 53 and the fixed charge film 51, and can suppress deterioration of dark characteristics. From the viewpoint of anti-reflection, it is preferable that the insulating film 52 have a lower refractive index than the upper film constituting the fixed charge film 51. For example, a silicon oxide (SiO₂) and a composite material mainly composed of silicon oxide (SiON, SiOC, and the like) can be used. A portion of the insulating film 52 provided between the metal of the light-shielding film 57 and the color filter 53 functions as a protective film. The protective film can avoid a mixing layer caused by contact between the metal of the light-shielding film 57 and the material of the color filter 53, or can avoid changes in the mixing layer that occur during a reliability test.

The color filter 53 is arranged for each pixel 3. The color filter 53 is a filter that selectively transmits any color selected from a plurality of different colors (for example, red, green, and blue, or cyan, magenta, and yellow). The color filter 53 may be made of pigment or dye, for example. The film thickness of the color filter 53 may be different for each color in consideration of color reproducibility based on the spectroscopic spectrum and sensor sensitivity specifications.

The on-chip lens 54 focuses the incident light on a photoelectric conversion unit 22 so that the incident light does not hit the light-shielding film 57 between the pixels. This on-chip lens 54 is arranged for each pixel 3. The on-chip lens 54 focuses light on the photoelectric conversion unit 22 by utilizing the difference in refractive index. Therefore, when the difference in refractive index between the on-chip lens 54 and the planarization film 56 covering the on-chip lens 54 becomes smaller, it becomes difficult for light to gather at the photoelectric conversion unit 22. Therefore, it is desirable to use a material with a high refractive index as the material constituting the on-chip lens 54, and to use a material with a low refractive index as the material constituting the planarization film 56.

It is desirable that the on-chip lens 54 be made of a high-refractive-index material having a refractive index of 1.6 or more. The on-chip lens 54 is made of an inorganic material such as silicon nitride or silicon oxynitride (SiON), for example. The refractive index of silicon nitride is about 1.9, and the refractive index of silicon oxynitride is about 1.45 or more and 1.9 or less. The on-chip lens 54 may be made of a material in which various organic films contain a high-refractive-index material. For example, the on-chip lens 54 may be made of a material in which various organic films contain titanium oxide (TiO₂) having a refractive index of about 2.3.

The planarization film 56 is for planarizing the unevenness formed by the on-chip lens 54. It is desirable that the planarization film 56 is made of a low-refractive-index material having a refractive index of 1.2 or more and 1.5 or less, for example. The planarization film 56 is made of an organic material, such as, for example, a siloxane resin, a styrene resin, an acrylic resin, a styrene-acrylic copolymer resin, an F-containing material (fluorine-containing material) of the resin, or a material in which the resin is filled with beads having a refractive index lower than that of the resin. Alternatively, the planarization film 56 may be made of inorganic materials such as silicon oxide, niobium oxide (Nb₂O₅), tantalum oxide (Ta₂O₅), aluminum oxide (Al₂O₃), hafnium oxide (HfO₂), silicon nitride, silicon nitride oxide, silicon carbide (SiC), or silicon oxycarbide (SiOC), silicon nitride carbide, or zirconium oxide (ZrO₂), and stacked structures of these inorganic materials, and the planarization film 56 may be planarized by chemical mechanical polishing (CMP) or the like. The present embodiment will be described assuming that the planarization film 56 is made of an organic film.

The light-shielding film 57 is disposed closer to the semiconductor layer 20 than the on-chip lens 54 in the boundary region of the pixel 3, and shields stray light leaking from adjacent pixels. The light-shielding film 57 may be made of any material that blocks light, and it is preferable to use a metal film such as, for example, aluminum (Al), tungsten (W), or copper (Cu) as materials that have strong light-shielding properties and can be precisely processed by microfabrication such as etching. The light-shielding film 57 can be also made of silver (Ag), gold (Au), platinum (Pt), molybdenum (Mo), chromium (Cr), titanium (Ti), nickel (Ni), iron (Fe), and tellurium (Te) or an alloy containing these metals, or it can be constructed by stacking a plurality of the above-mentioned materials. In order to improve the adhesion with the underlying insulating film 52, a barrier metal such as, for example, titanium (Ti), tantalum (Ta), tungsten (W), cobalt (Co), molybdenum (Mo), an alloy thereof, a nitride thereof, an oxide thereof, or a carbide thereof may be included below the light-shielding film 57. The light-shielding film 57 may also serve as a light shield for pixels that determine the optical black level, and may also serve as a light shield for preventing noise from entering the peripheral circuit region. It is desirable that the light-shielding film 57 is grounded so as not to be destroyed by plasma damage caused by accumulated charges during processing. For example, the light-shielding film 57 may be provided with a grounding structure in a region outside the effective region so that all the light-shielding films are electrically connected.

### <Semiconductor Layer>

As shown in FIG. 4A, the light detection device 1 and the semiconductor layer 20 included in the light detection device 1 are curved together with the multilayer filter 60. As shown in FIG. 4B, the semiconductor layer 20 is made of a semiconductor substrate. The semiconductor layer 20 is made of, for example, a single crystal silicon substrate. In the semiconductor layer 20, a photoelectric conversion region 20a is provided for each pixel 3. For example, an island-shaped photoelectric conversion region 20a partitioned by an isolation region 20b is provided for each pixel 3. That is, the semiconductor layer 20 has a light-receiving region 20C formed by arranging a plurality of photoelectric conversion regions 20a in a two-dimensional array. Light that has passed through the multilayer filter can be incident on each of the plurality of photoelectric conversion regions 20a.

The photoelectric conversion region 20a includes a well region 21 of a first conductivity type (for example, p-type), and a photoelectric conversion unit 22 that is a semiconductor region of a second conductivity type (for example, n-type) buried inside the well region 21. A photoelectric conversion element PD shown in FIG. 3 is configured within the photoelectric conversion region 20a. Photoelectric conversion can be performed in at least a portion of the photoelectric conversion region 20a.

The isolation region 20b has, but not limited to, for example, a trench structure in which an isolation trench is formed in the semiconductor layer 20 and an insulating film 52 is embedded in the isolation groove. In this way, crosstalk caused by rolling electrons can be blocked by the insulating film 52, and crosstalk in the form of light can also be suppressed by interfacial reflection due to the difference in refractive index. Alternatively, the isolation region 20b may be formed of a p-type semiconductor region and may be grounded, for example.

Here, one surface of the semiconductor layer 20 is referred to as a first surface S1, and the other surface is referred to as a second surface S2. The first surface S1 is sometimes referred to as an element formation surface or a main surface, and the second surface S2 is sometimes referred to as a back surface. Furthermore, in the present embodiment, since the light detection device 1 is a back-illuminated CMOS image sensor, light enters the semiconductor layer 20 from the second surface S2 side. Therefore, the second surface S2 may be referred to as a light-receiving surface.

### <Wiring Layer>

The wiring layer 30 includes an insulating film 31, wiring 32, and via-plugs. The wiring 32 is for transmitting image signals generated by the pixels 3. Further, the wiring 32 further transmits signals applied to the pixel circuit. Specifically, the wiring 32 constitutes various signal lines (pixel drive line 10 and the like) and a power source line Vdd shown in FIGS. 2 and 3. The wiring 32 and the pixel circuit are connected by via-plugs. Further, the wiring layer 30 is composed of multiple layers, and the layers of each wiring 32 are also connected by via-plugs. The wiring 32 can be made of metal such as aluminum (Al) or copper (Cu), for example. The via-plug can be made of metal such as tungsten (W) or copper (Cu), for example. For example, a silicon oxide film or the like can be used as the insulating film 31.

### <Support Substrate>

The support substrate 40 is a substrate that reinforces and supports the semiconductor layer 20 and the like during the manufacturing process of the light detection device 1, and is made of, for example, a silicon substrate. The support substrate 40 is attached to the wiring layer 30 by plasma bonding or an adhesive material, and supports the semiconductor layer 20 and the like. The support substrate 40 may include a logic circuit, and the chip size can be reduced by forming connection vias between the substrates and vertically stacking various peripheral circuit functions.

### <<Method of Manufacturing Light Detection Device>>

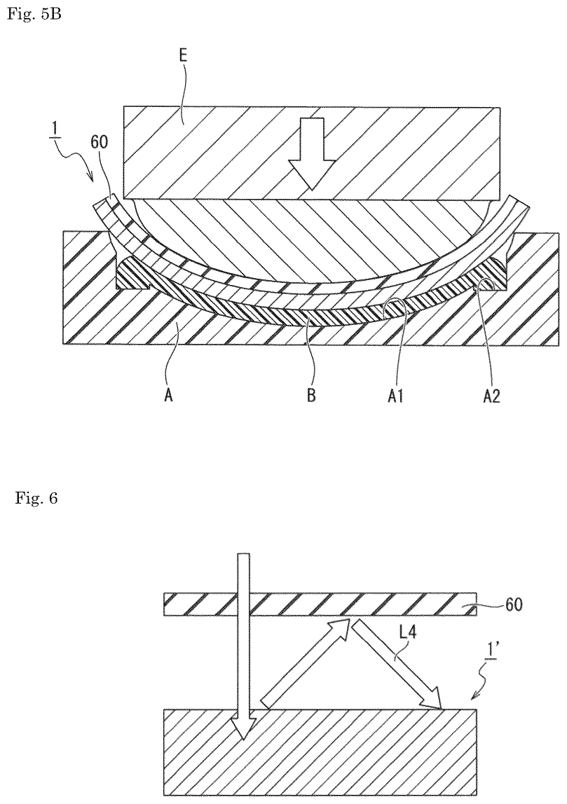

Hereinafter, a method of manufacturing the light detection device 1 will be described with reference to FIGS. 5A and 5B. First, the light detection device 1 (semiconductor chip 2) shown in FIG. 5A is prepared. At the stage shown in FIG. 5A, the light detection device 1 has not yet been bent. More specifically, the support substrate 40 to the on-chip lens 54 shown in FIG. 4B are formed using a known method. Thereafter, the planarization film 56 and the multilayer filter 60 are stacked in this order on the exposed surface of the on-chip lens 54. In this way, the light detection device 1 before being bent is obtained. Hereinafter, a method of forming the planarization film 56 and the multilayer filter 60 will be described in detail.

The planarization film 56 is formed by, for example, spin coating using an organic material, such as a siloxane resin, a styrene resin, an acrylic resin, a styrene-acrylic copolymer resin, an F-containing material of the resin, or a material in which the resin is filled with beads having a refractive index lower than that of the resin. Alternatively, the planarization film 56 may be formed by CVD, sputtering, or the like using inorganic materials such as silicon oxide, niobium oxide, tantalum oxide, aluminum oxide, hafnium oxide, silicon nitride, silicon nitride oxide, silicon carbide, silicon oxycarbide, silicon nitride carbide, or zirconium oxide, and stacked structures of these inorganic materials. In the case of an inorganic material, since unevenness occurs on the exposed surface along the on-chip lens 54, it is desirable to planarize it by CMP. At this time, it is more desirable to form the planarization film 56 to have a thicker initial film thickness so that the upper end of the on-chip lens 54 is not polished.

Next, the multilayer filter 60 is formed on the exposed surface of the planarization film 56. The multilayer filter 60 is formed by CVD, ALD, sputtering, or the like so that the above-described high-refractive-index material and low-refractive-index material have desired film thicknesses. After that, the wafer is cut into pieces to obtain the light detection device 1 before being bent.

Thereafter, the light detection device 1 is mounted on the pedestal A shown in FIG. 5A while being curved. More specifically, the light detection device 1 is fixed to one surface A1 (curved surface) of the pedestal A via an adhesive B. At this time, as shown in FIG. 5B, the exposed surface of the light detection device 1 is pressed by the pressing portion E, thereby fixing the light detection device 1 along one surface A1 of the pedestal A. Then, when the light detection device 1 is pressed by the pressing portion E, the excess adhesive B flows into the groove A2. The type of the adhesive B is not particularly limited, and may be an ultraviolet curing type, a temperature curing type, a time effect type, or the like.

### <<Main Effects of First Embodiment>>

The main effects of the first embodiment will be described below, but before that, a conventional example will be described. In the conventional example shown in FIG. 6, the multilayer filter 60 was not provided integrally with a light detection device 1′. The multilayer filter 60 was provided at a position separated from the light detection device 1′ by a millimeter order. Therefore, the light that was diffracted and reflected inside the light detection device 1′ was further reflected by the interface of the multilayer filter 60 to become light L4, which entered the semiconductor layer 20. If the multilayer filter 60 and the light detection device 1′ was separated, the light L4 will be incident on the pixel 3 located away from the pixel 3 on which the principal ray has entered, so the region where flare will occur will be widened.

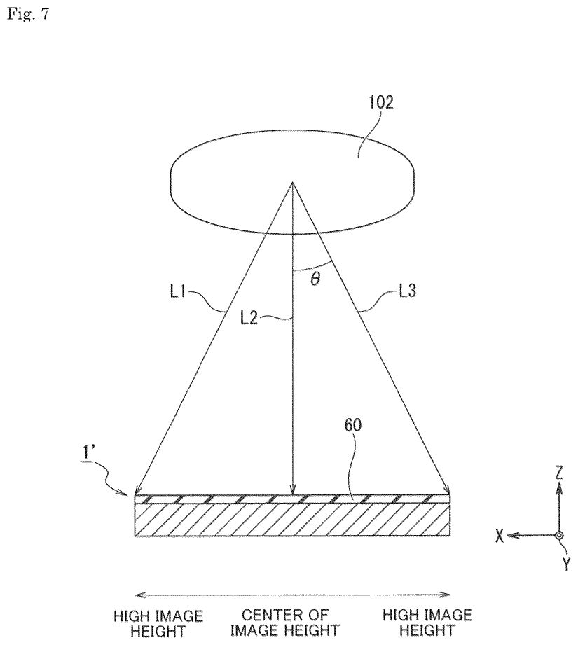

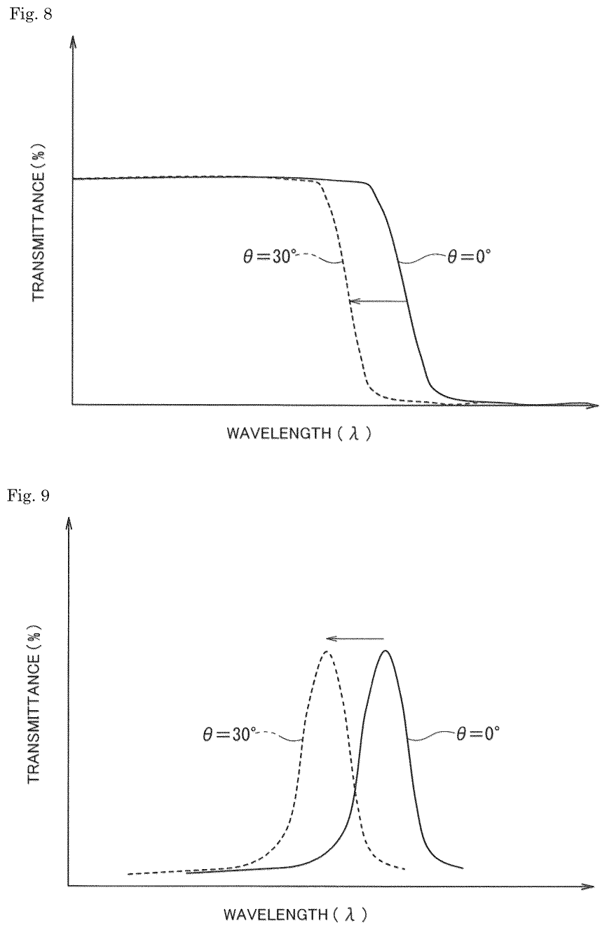

In the conventional example shown in FIG. 7, the light detection device 1′ and the multilayer filter 60 are not curved but flat. The principal ray L2 traveling along the Z direction is suppressed from entering the multilayer filter 60 at an angle far from vertical. However, the principal rays L1 and L3 that travel obliquely with respect to the Z direction are incident obliquely on the portion of the multilayer filter 60 that is stacked near the edge of the light-receiving region 20C (position where the image height is high). Therefore, the optical path lengths of the principal rays L1 and L3 within the multilayer filter 60 were longer than the optical path length of the principal ray L2. As the optical path lengths of the principal rays L1 and L3, which are oblique lights, become longer, the cutoff wavelength of the multilayer filter 60 is greatly shifted to the shorter wavelength side. For example, when the principal rays L1 and L3 are incident on the multilayer filter 60 at θ=30°, as shown in FIG. 8, the principal rays will be greatly shifted to the shorter wavelength side compared with the case where the cutoff wavelength of the multilayer filter 60 is θ=0°. Therefore, part of the light with a wavelength that passes through the multilayer filter 60 (for example, part of red light) when θ=0° will be reflected by the multilayer filter 60 when θ=30°, and the light would not be able to pass through the multilayer filter 60. Therefore, there was a possibility that some of the red light would not reach the photoelectric conversion unit 22 on the image plane where the image height is high. Therefore, on an image plane with a high image height, there was a possibility that red light becomes thinner and color reproducibility deteriorates.

In contrast, in the light detection device 1 according to the first embodiment of the present technology, the multilayer filter 60 is integrally stacked on the light detection device 1. Therefore, as shown in FIG. 4E, it is possible to suppress the light L4 from entering the pixel 3 located far away in plan view and suppress the region where flare occurs from widening.

Furthermore, in the light detection device 1 according to the first embodiment of the present technology, the multilayer filter 60 is convexly curved toward the semiconductor layer 20 (the center of the light-receiving region 20C) not for each pixel 3 but as a whole. Therefore, even if the principal ray is incident on the stacked portion of the multilayer filter 60 near the edge of the light-receiving region 20C (position where the image height is high), it is possible to suppress the light from being incidence on the multilayer filter 60 at an angle far from vertical. In this way, the optical path length of the principal ray (for example, principal rays L1, L3) that travel obliquely is suppressed from becoming longer than the optical path length of the principal ray L2 in the multilayer filter 60, and it is possible to suppress a large shift of the cutoff wavelength of the principal rays L1 and L3 toward the shorter wavelength side. As a result, even if the light is oblique light, light such as part of red light that is originally designed to pass through the multilayer filter 60 can be suppressed from being reflected by the multilayer filter 60, and deterioration of color reproducibility can be suppressed at positions of the image plane where the image height is high.

### Modified Examples of First Embodiment

Hereinafter, modified examples of the first embodiment will be described.

### Modified Example 1

Although the multilayer filter 60 of the light detection device 1 according to the first embodiment is an infrared-cut filter that transmits visible light and reflects infrared rays having a longer wavelength than visible light, the present technology is not limited thereto. In Modified Example 1 of the first embodiment, the multilayer filter 60 may be a bandpass filter. The wavelength band of light transmitted by a bandpass filter is usually narrower than the wavelength band transmitted by an infrared-cut filter. The light transmitted by the bandpass filter may be part of visible light, or may be light other than visible light such as infrared light. Alternatively, the ultraviolet sensor may be configured to transmit ultraviolet light.

In the conventional light detection device 1′, as shown in FIG. 9, the cutoff wavelength of the multilayer filter 60, which is a bandpass filter, is greatly shifted to the shorter wavelength side. On the other hand, in the light detection device 1 according to Modified Example 1 of the first embodiment, it is possible to suppress the cutoff wavelengths of the principal rays L1 and L3 from shifting significantly toward the shorter wavelength side.

Also in the case of the light detection device 1 according to Modified Example 1 of the first embodiment, effects similar to those of the light detection device 1 according to the first embodiment described above can be obtained.

### Modified Example 2

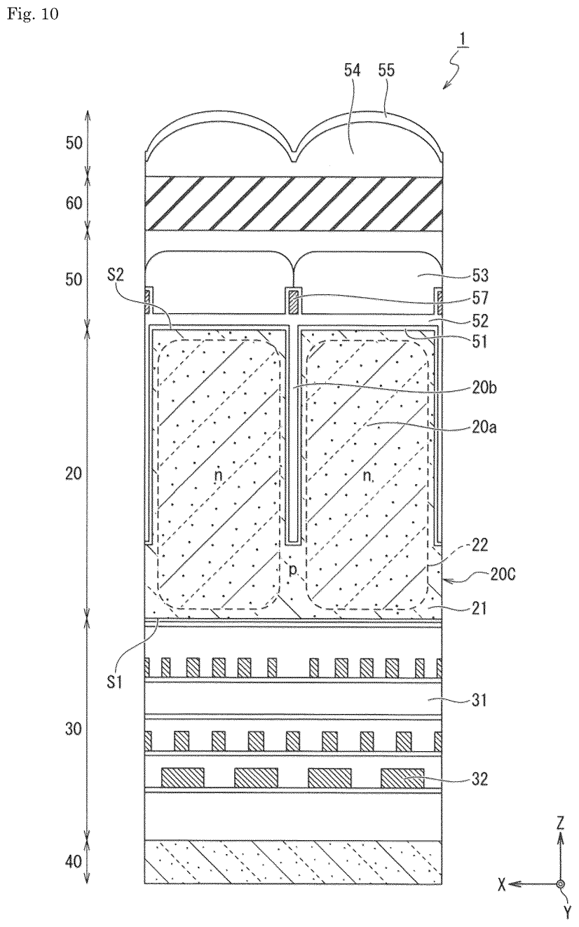

Although the multilayer filter 60 of the light detection device 1 according to the first embodiment is provided upstream of the on-chip lens 54 in the light traveling direction, the present technology is not limited thereto. As shown in FIG. 10, in Modified Example 2 of the first embodiment, the multilayer filter 60 is provided between the on-chip lens 54 and the color filter 53.

Also in the case of the light detection device 1 according to Modified Example 2 of the first embodiment, effects similar to those of the light detection device 1 according to the first embodiment described above can be obtained.

### Modified Example 3

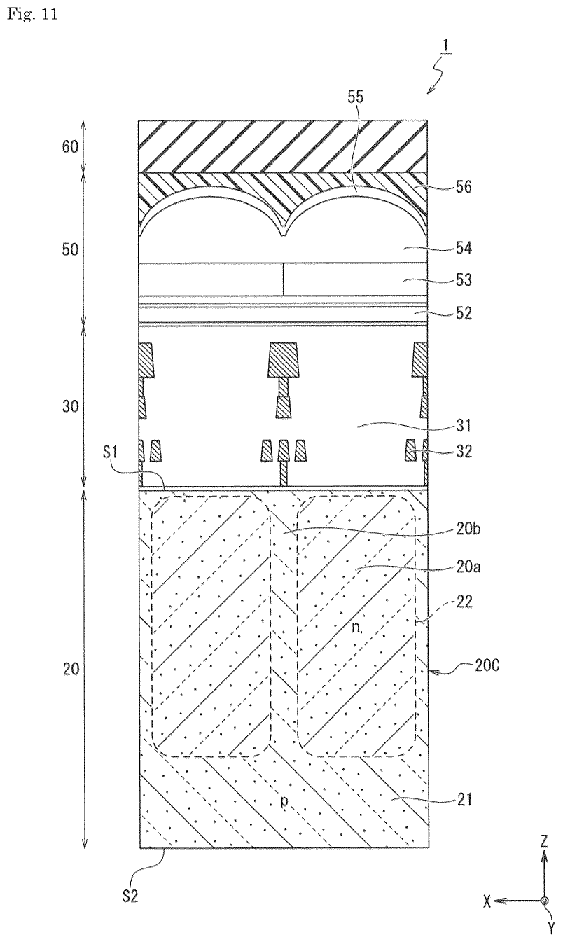

Although the light detection device 1 according to the first embodiment is a back-illuminated CMOS image sensor, the present technology is not limited thereto. As shown in FIG. 11, in Modified Example 3 of the first embodiment, the light detection device 1 may be a front-illuminated CMOS image sensor.

Also in the case of the light detection device 1 according to Modified Example 3 of the first embodiment, effects similar to those of the light detection device 1 according to the first embodiment described above can be obtained.

### Modified Example 4

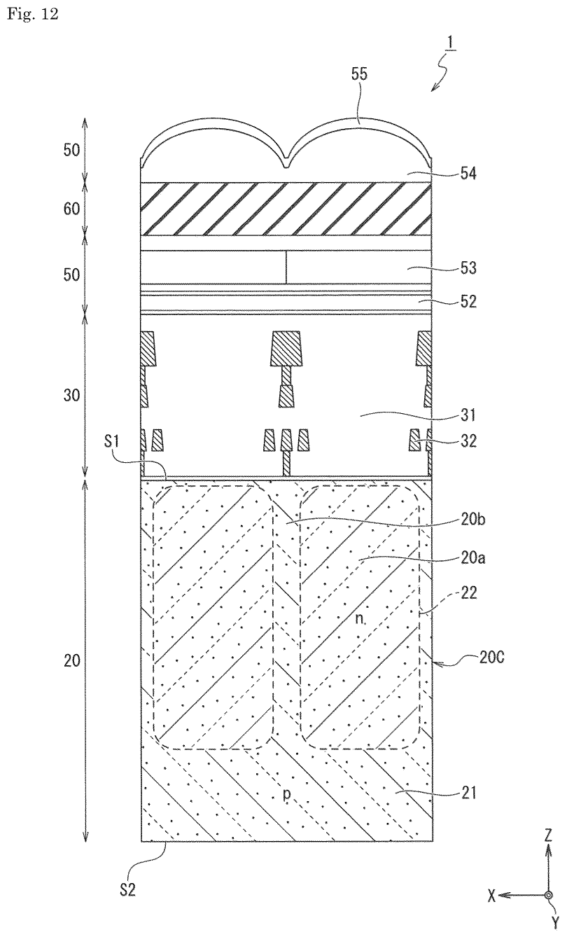

Although the multilayer filter 60 of the light detection device 1 according to Modified Example 3 of the first embodiment is provided upstream of the on-chip lens 54 in the light traveling direction, the present technology is not limited thereto. As shown in FIG. 12, in Modified Example 4 of the first embodiment, the multilayer filter 60 is provided between the on-chip lens 54 and the color filter 53.

Also in the case of the light detection device 1 according to Modified Example 4 of the first embodiment, effects similar to those of the light detection device 1 according to the first embodiment described above can be obtained. Also in the case of the light detection device 1 according to Modified Example 4 of the first embodiment, effects similar to those of the light detection device 1 according to Modified Example 3 of the first embodiment described above can be obtained.

### Modified Example 5

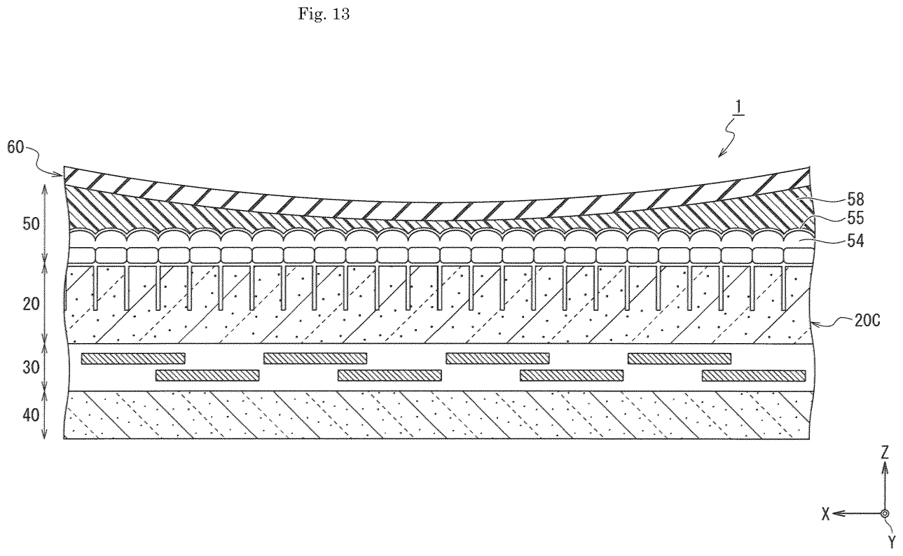

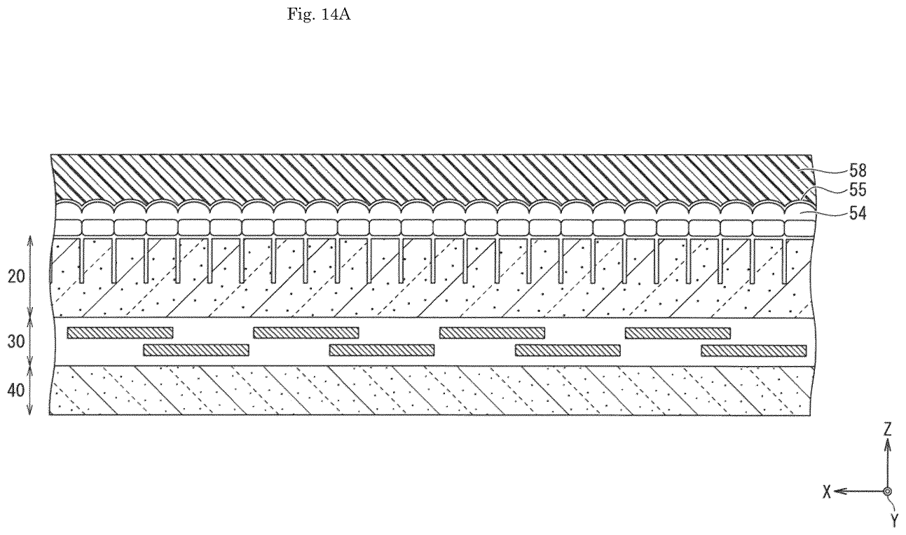

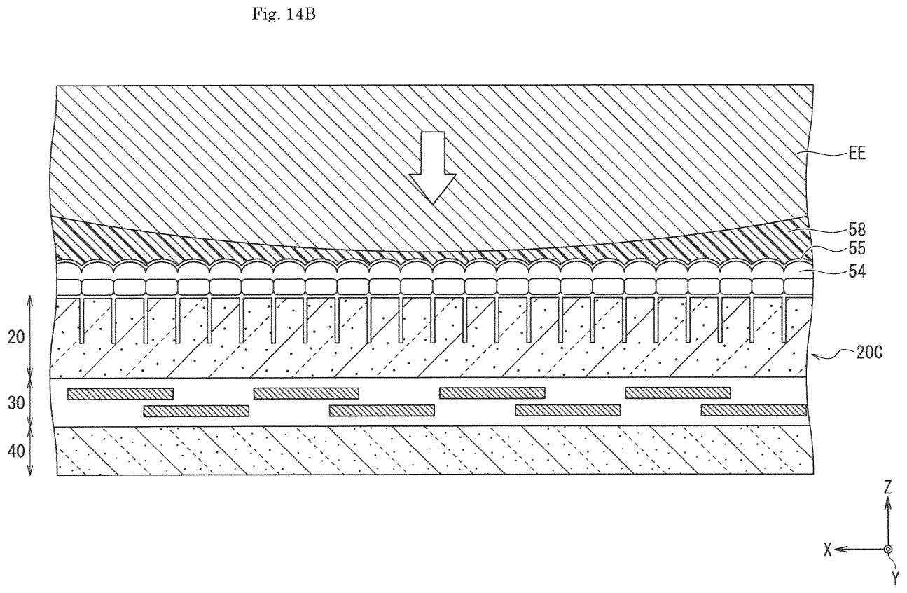

Although the semiconductor layer 20 of the light detection device 1 according to the first embodiment is curved together with the multilayer filter 60, the present technology is not limited thereto. As shown in FIG. 13, in Modified Example 5 of the first embodiment, the semiconductor layer 20 is flat, and the multilayer filter 60 among the semiconductor layer 20 and the multilayer filter 60 is curved.

The semiconductor layer 20, the wiring layer 30, and the support substrate 40 are not curved and are flat. The light-receiving-surface-side stacked body 50 has an insulating layer 58 instead of the planarization film 56. The components of the light-receiving-surface-side stacked body 50 other than the insulating layer 58 are provided flatly along the semiconductor layer 20. The insulating layer 58 is provided between the semiconductor layer 20 and the multilayer filter 60. More specifically, the insulating layer 58 is provided between the on-chip lens 54 and the multilayer filter 60. On the semiconductor layer 20 side of the insulating layer 58, the unevenness of the on-chip lens 54 is planarized. The surface of the insulating layer 58 opposite to the semiconductor layer 20 side is not formed flat, but is a curved surface convexly curved toward the semiconductor layer 20. Since the multilayer filter 60 is stacked on the curved surface of the insulating layer 58, it is curved along the curved surface of the insulating layer 58. The insulating layer 58 is, for example, but not limited to, a resist used in imprint lithography, and has a refractive index of, for example, 1.2 or more and 1.5 or less. The on-chip lens is preferably made of a material with a high refractive index, such as silicon nitride.

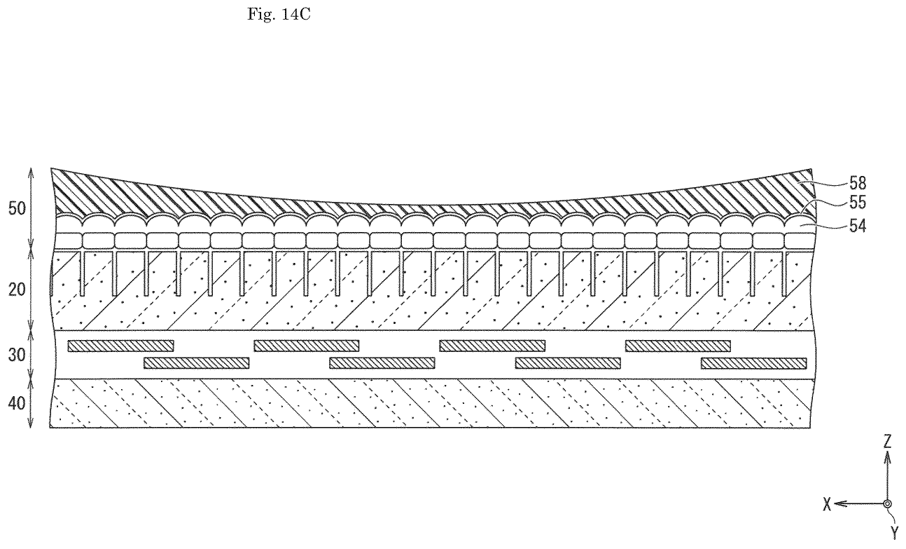

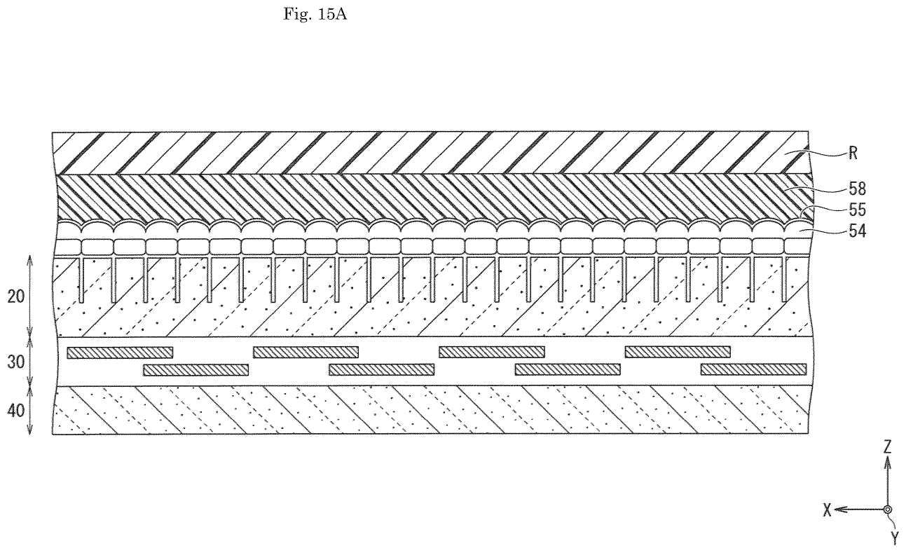

Hereinafter, a method of manufacturing the light detection device 1 will be described with reference to FIGS. 14A to 14C. First, a substrate including the support substrate 40 to the on-chip lens 54 of the light detection device 1 is prepared. Thereafter, as shown in FIG. 14A, a resist for imprint lithography before being cured is spin-coated on the exposed surface of the on-chip lens 54 as the insulating layer 58. Thereafter, as shown in FIG. 14B, the insulating layer 58 is pressed with a mold EE and irradiated with ultraviolet rays so as to be temporarily cured. At this time, only the region of the insulating layer 58 that overlaps the pixel region 2A in plan view is temporarily cured. The mold EE is made of a material that transmits ultraviolet rays.

Then, as shown in FIG. 14C, the mold EE is separated from the insulating layer 58 to obtain a curved surface of the insulating layer 58 that is convexly curved toward the semiconductor layer 20. Thereafter, by development, the portions of the insulating layer 58 that have not been temporarily cured are washed away. Then, the temporarily cured insulating layer 58 is further irradiated with ultraviolet rays to perform heat treatment. Thereafter, although not shown in the figure, the multilayer filter 60 is stacked on the curved surface.

Also in the case of the light detection device 1 according to Modified Example 5 of the first embodiment, effects similar to those of the light detection device 1 according to the first embodiment described above can be obtained.

### Modified Example 6

Modified Example 6 of the first embodiment will be described using FIG. 13 of Modified Example 5 of the first embodiment. In Modified Example 6 of the first embodiment, the material constituting the insulating layer 58 is different from that in Modified Example 5 of the first embodiment described above. The insulating layer 58 is not a resist for imprint lithography, but is made of the same material as the planarization film 56.

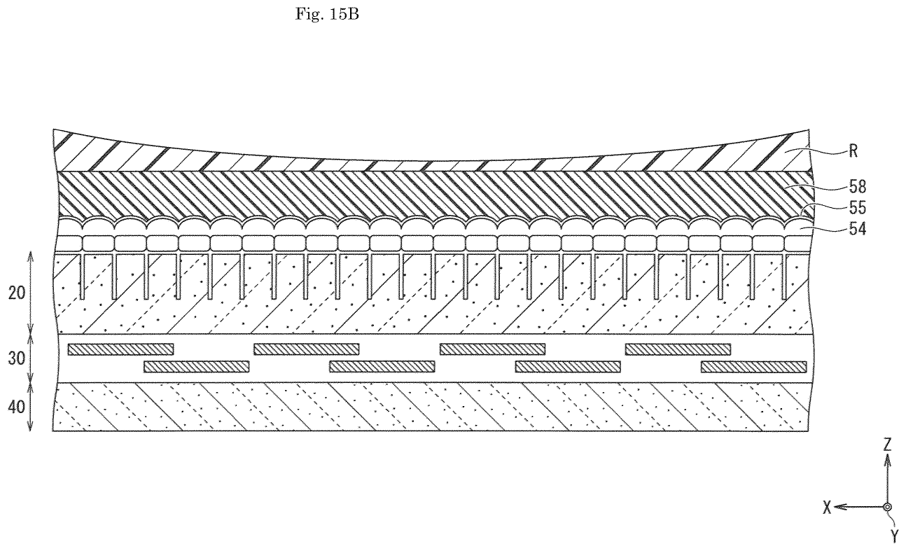

Hereinafter, a method of manufacturing the light detection device 1 will be described with reference to FIGS. 15A and 15B. A substrate having the support substrate 40 to the on-chip lens 54 is prepared. Then, as shown in FIG. 15A, an insulating layer 58 is formed on the exposed surface of the on-chip lens 54, and then a resist R is applied to the exposed surface of the insulating layer 58. Thereafter, exposure is performed using a known grayscale lithography technique to obtain the resist shape shown in FIG. 15B. In the resist shape shown in FIG. 15B, the film thickness of the resist R gradually becomes thinner toward the center of the pixel region 2A. Thereafter, the entire surface of the wafer is etched back to obtain the shape of the insulating layer 58 shown in FIG. 14C. Thereafter, a multilayer filter 60 is stacked on the curved surface of the insulating layer 58.

Also in the case of the light detection device 1 according to Modified Example 6 of the first embodiment, effects similar to those of the light detection device 1 according to the first embodiment described above can be obtained.

### Modified Example 7

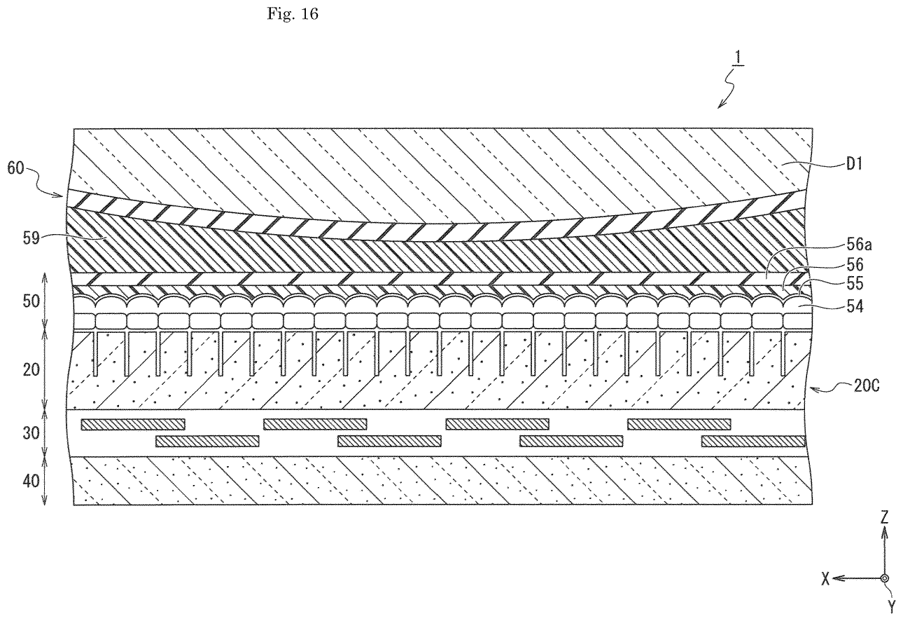

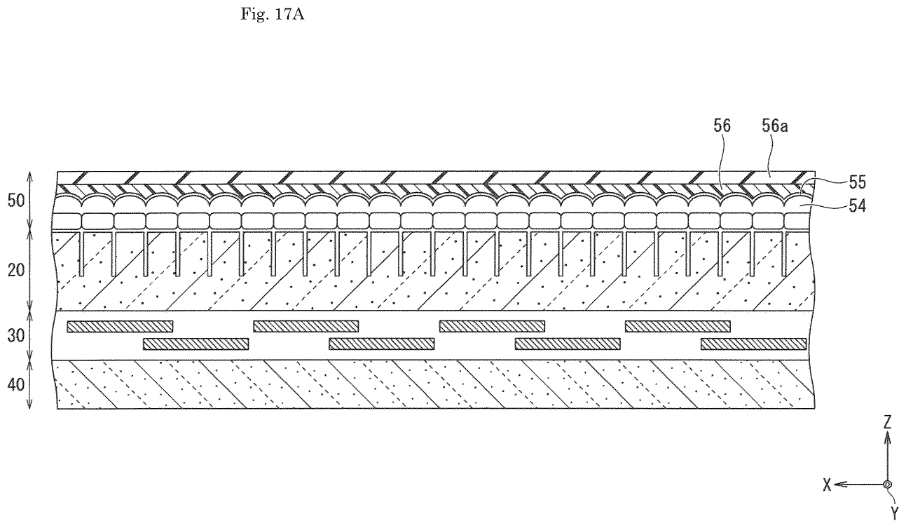

Although the semiconductor layer 20 of the light detection device 1 according to the first embodiment is curved together with the multilayer filter 60, the present technology is not limited thereto. As shown in FIG. 16, in Modified Example 7 of the first embodiment, the semiconductor layer 20 is flat, and the light detection device 1 is a chip size package (CSP), and has a sealing glass D1 in which the surface on the semiconductor layer 20 side is convexly curved toward the semiconductor layer 20.

The light-receiving-surface-side stacked body 50 includes a protective film 56a stacked on the planarization film 56. When the planarization film 56 is made of an organic film, it is preferable that a protective film 56a made of an inorganic material be stacked on the planarization film 56. The protective film 56a is made of, but not limited to, silicon oxide, for example.

The light detection device 1 includes a sealing glass D1 in which the surface on the semiconductor layer 20 side is convexly curved toward the semiconductor layer 20. The sealing glass D1 is a glass member. The multilayer filter 60 is provided along the curved surface of the sealing glass D1, and is curved along the curved surface of the sealing glass D1. An adhesive layer 59 is provided between the multilayer filter 60 and the protective film 56a of the light detection device 1. The adhesive layer 59 is formed by curing adhesive with heat or ultraviolet rays, and connects the sealing glass D1 on which the multilayer filter 60 is stacked and the protective film 56a.

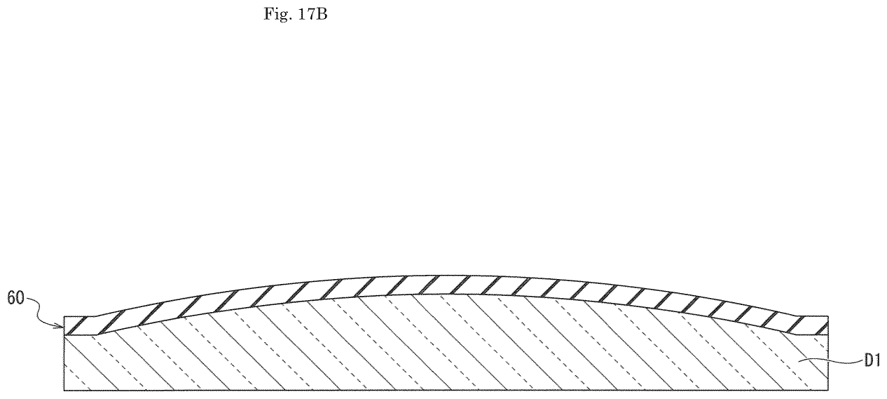

Hereinafter, a method of manufacturing the light detection device 1 will be described with reference to FIGS. 17A and 17B. The manufacturing method from the support substrate 40 to the planarization film 56 has already been explained in the first embodiment, so a description thereof will be omitted. As shown in FIG. 17A, a protective film 56a is stacked on the exposed surface of the planarization film 56 to prepare a substrate having the support substrate 40 to the protective film 56a. A sealing glass D1 and a multilayer filter 60 are prepared separately from the substrate including the support substrate 40 to the protective film 56a. As shown in FIG. 17B, one surface of the sealing glass D1 is processed to have a convex shape as a whole to obtain a curved surface. Then, the multilayer filter 60 is stacked on the curved surface of the sealing glass D1. Thereafter, the protective film 56a of the prepared substrate and the multilayer filter 60 side of the prepared sealing glass D1 are connected with an adhesive. Then, the adhesive is cured by heat or ultraviolet rays to obtain the adhesive layer 59. The substrate side and the sealing glass D1 side may be prepared from either side, and are not particularly limited.

Also in the case of the light detection device 1 according to Modified Example 7 of the first embodiment, effects similar to those of the light detection device 1 according to the first embodiment described above can be obtained.

### Second Embodiment

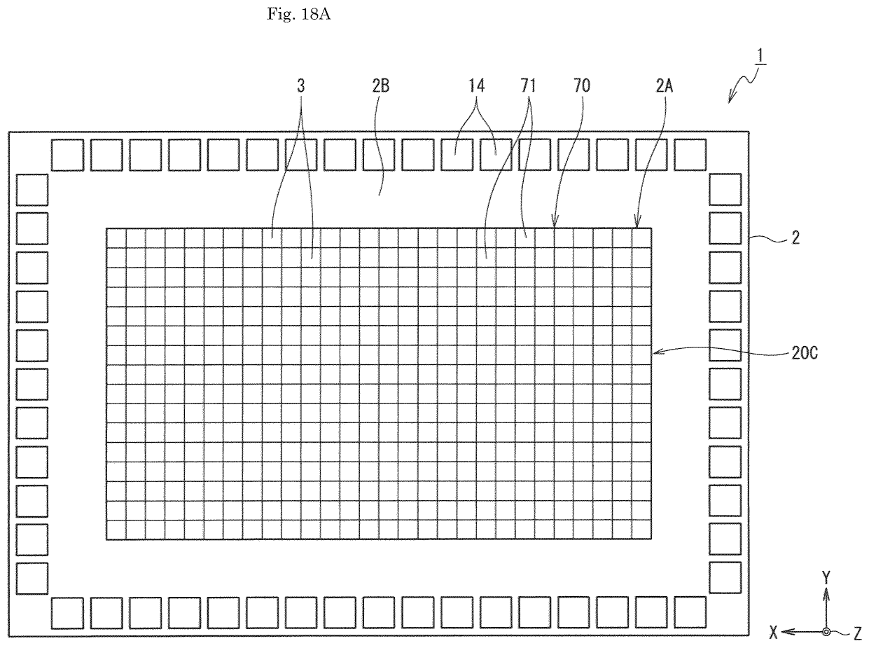

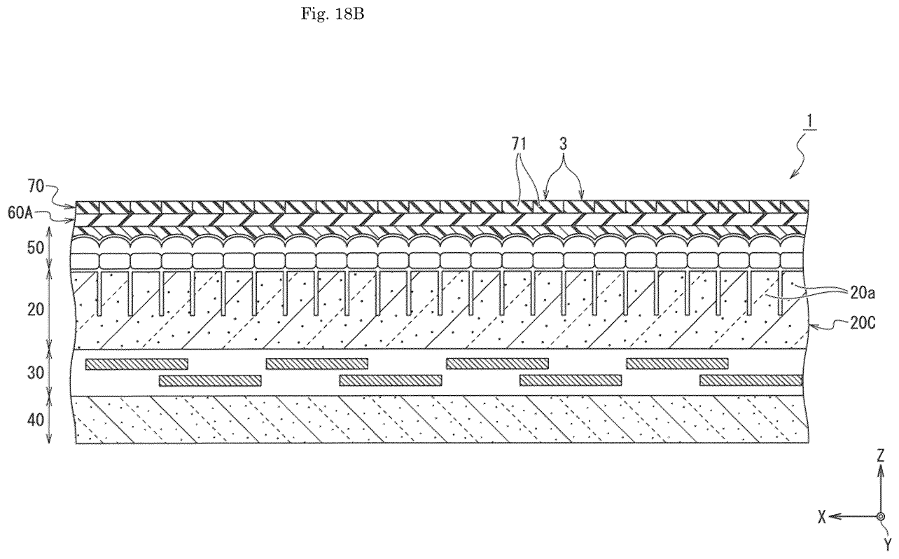

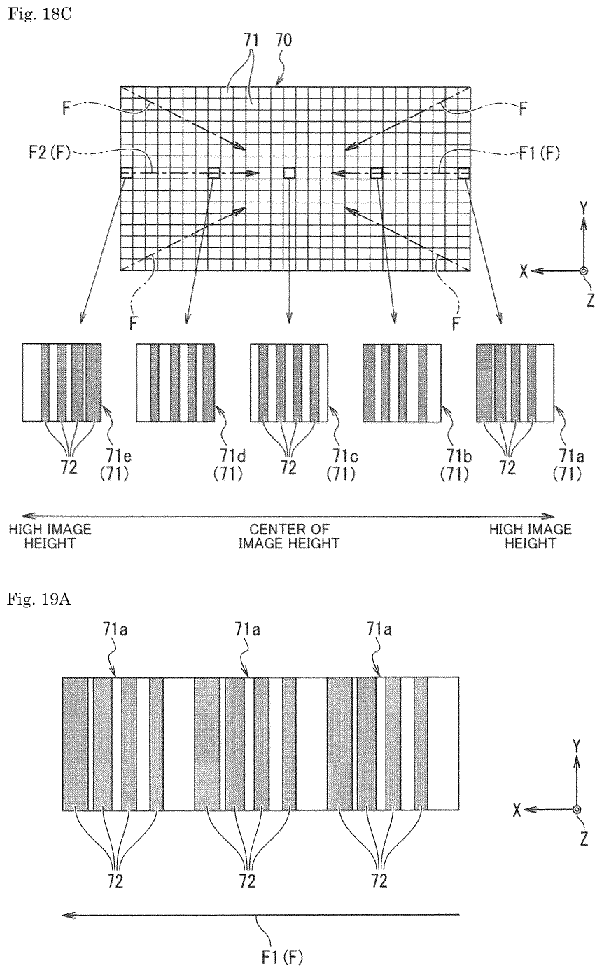

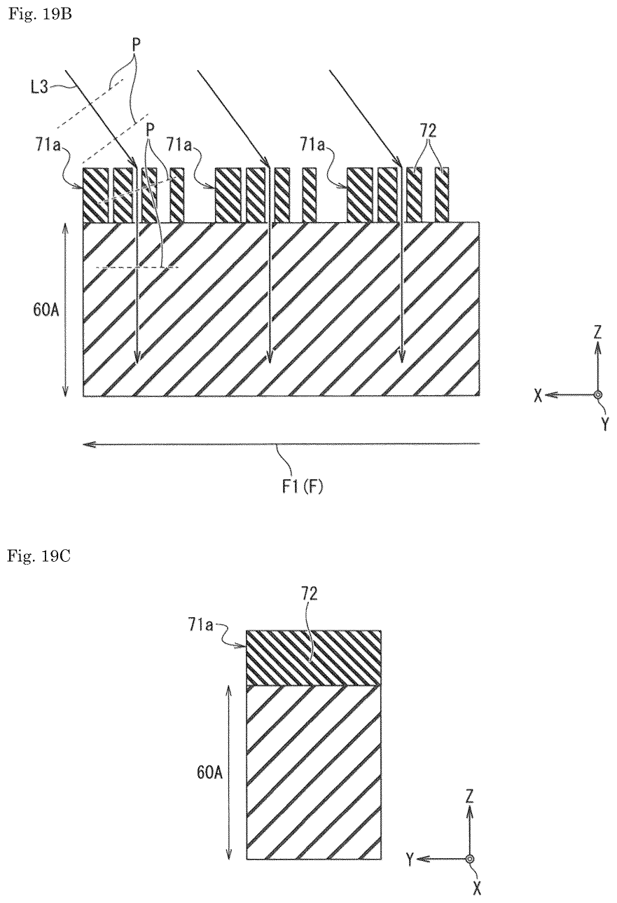

A second embodiment of the present technology shown in FIGS. 18A to 18C and FIGS. 19A to 19C will be described below. The light detection device 1 according to the second embodiment is different from the light detection device 1 according to the first embodiment described above in that it is provided with an optical element 71 instead of the multilayer filter 60 being curved. The other configuration of the light detection device 1 is basically the same as that of the light detection device 1 of the first embodiment described above. The same reference signs will be assigned to constituent elements that have already been described, and description thereof will be omitted.

### <<Specific Configuration of Light Detection Device>>

The configuration of the light detection device 1 according to the second embodiment of the present technology will be described below, focusing on the parts that are different from the configuration of the light detection device 1 according to the above-described first embodiment.

### <Stacked Structure of Light Detection Device>

As shown in FIG. 18B, the light detection device 1 (semiconductor chip 2) has a stacked structure in which an optical element layer 70, a multilayer filter 60A, a light-receiving-surface-side stacked body 50, a semiconductor layer 20, a wiring layer 30, and a support substrate 40 are stacked in this order. The optical element layer 70 and the multilayer filter 60A are integrally stacked on the light detection device 1. More specifically, the optical element layer 70 and the multilayer filter 60A are integrally stacked on the light detection device 1. The multilayer filter 60A is provided so as to continuously cover at least the pixel region 2A without interruption.

### <Optical Element Layer>

The optical element layer 70 is provided at a position overlapping at least the pixel region 2A (light-receiving region 20C) in plan view. As shown in FIG. 18A, the optical element layer 70 is provided at a position that exactly overlaps the pixel region 2A (light-receiving region 20C) in plan view. The optical element layer 70 is formed by arranging a plurality of optical elements 71 in a two-dimensional array. As shown in FIG. 18B, the optical element 71 is provided for each pixel 3, that is, for each photoelectric conversion region 20a. One optical element 71 is provided at a position overlapping one photoelectric conversion region 20a in plan view. Note that the light-receiving region 20C is a region formed by arranging a plurality of photoelectric conversion regions 20a in a two-dimensional array in the semiconductor layer 20. Then, the light having passed through the multilayer filter 60A enters the photoelectric conversion region 20a.

### <Optical Element>

FIGS. 19A, 19B, and 19C show an optical element 71a shown in FIG. 18C as an example of the optical element 71. FIGS. 19A, 19B, and 19C show an example in which three optical elements 71a are arranged along the X direction. As shown in FIG. 19B, the optical element 71 is a metasurface optical element provided to deflect the traveling direction of the principal ray closer to the Z direction. Therefore, the optical element 71 is provided upstream of the multilayer filter 60A in the light traveling direction. Here, the metasurface optical element is an optical element that has a plurality of artificial structures 72 having a width sufficiently smaller than the wavelength of light and exhibits physical properties and functions not found in nature. As shown in FIG. 19B, the principal ray L3 obliquely incident on the optical element 71a is deflected by the optical element 71a so that its traveling direction approaches the Z direction. Since the traveling direction of the principal ray L3 is deflected by the optical element 71, it is possible to suppress the principal ray L3 from being incident on the multilayer filter 60A at an angle far from vertical.

One optical element 71 has a plurality of structures 72 arranged at intervals in the width direction in plan view. In the present embodiment, the structure 72 has a plate-like shape and extends linearly in the longitudinal direction in plan view. Note that the number of structures 72 included in one optical element 71 is not limited to the number shown. The width direction is the width direction of the structure 72. More specifically, it is the lateral direction among the longitudinal direction and the lateral direction when the structure 72 is viewed in plan view. In a plan view, the pitch of the structures 72 in the width direction is equal to or less than the wavelength of the target light. For example, in the visible range of 400 to 650 nm, it is desirable to set the pitch to less than 400 nm which is the short wavelength end. In this manner, stray light due to diffraction can be suppressed. As shown in FIGS. 19B and 19C, the height direction of the structure 72 is along the Z direction. The dimensions in the height direction of the structures 72 are on the submicron order, and are approximately the same for the plurality of structures 72.

The structure 72 is made of a material that transmits light. Preferably, the structure 72 is made of a material with a high refractive index. Examples of the material constituting the structure 72 include silicon nitride (Si₃N₄), titanium oxide (TiO₂), tantalum oxide (Ta₂O₅), and aluminum oxide (Al₂O₃). The present embodiment will be described assuming that the structure 72 is made of silicon nitride. In addition, the portion of the optical element 71 where the structure 72 is not provided is occupied by air, for example, but the present technology is not limited thereto. A portion of the optical element 71 where the structure 72 is not provided may be provided with a material having a lower refractive index than the material forming the structure 72 (for example, silicon oxide).

As shown in FIG. 19A, the density of the structures 72 in one optical element 71a in plan view is higher for the optical element 71a on the left side of the paper (portion closer to the center of the light-receiving region 20C) than on the right side of the paper (portion closer to the edge of the light-receiving region 20C). That is, the distribution of the optical element 71a on the left side and right side of the paper is asymmetric with respect to the center in the left-right direction of the paper. Note that this is a feature when the optical element 71a is taken as an example, and in any (or all) optical elements 71 arranged so as to overlap a position away from the center of the light-receiving region 20C in plan view shown in FIG. 18C, the structure 72 has an asymmetrical distribution with respect to the center between the edge-side portion and the center-side portion of the light-receiving region 20C of the optical element 71 in plan view. More specifically, the density of the structures 72, which have a higher refractive index than air, in one optical element 71a in plan view gradually increases from the right side to the left side of the paper in FIG. 19A (along the direction F1). Therefore, the refractive index of one optical element 71a gradually increases from the right side to the left side of the paper. Gradually increasing the density of the structures 72 in one optical element 71a in plan view along the direction F1 can be achieved by at least one of gradually increasing the widthwise dimension of the structure 72 in one optical element 71a from the right side to the left side in the paper (along the direction F1) and gradually decreasing the arrangement pitch of the structures 72 from the right side to the left side of the paper (along the direction F1). Alternatively, for example, the arrangement pitch of the structures 72 may be kept constant, and the widthwise dimension of the structures 72 may be gradually increased from the right side to the left side of the paper (along the direction F1). The widthwise dimension of the structures 72 may be kept constant, and the arrangement pitch of the structures 72 may be gradually decreased from the right side to the left side of the paper (along the direction F1).

Such an optical element 71a can change the phase of the principal ray, as shown in FIG. 19B. More specifically, the optical element 71a can delay the phase of the principal ray in a portion where the structures 72 are densely provided. The optical element 71a is an optical element arranged so as to overlap a position away from the center of the light-receiving region 20C (a position where the image height is high) in plan view. Therefore, the principal ray L3 obliquely enters the optical element 71a. Further, the direction F1 is a direction from the edge of the light-receiving region 20C toward the center. When the principal ray L3 enters the optical element 71a, the wavefront P of the light extending in the direction perpendicular to the light traveling direction also obliquely enters the optical element 71a. The wavefront P of the light first enters a portion of the optical element 71a where the structures 72 are densely provided. In such a portion, the phase of the wavefront P is delayed. Then, the wavefront P is sequentially incident on the portion of the optical element 71a where the density of the structures 72 is low. In such a portion, the phase delay of the wavefront P is gradual, if at all, compared to a portion where the density of the structures 72 is high. As a result, a portion of the wavefront P obliquely incident on the optical element 71a is created with a delay, the wavefront P is rotated along the direction perpendicular to the plane of the drawing, and the traveling direction of the principal ray L3 is deflected. In this way, by arranging the plurality of structures 72 so as to gradually become denser along the direction (direction F1) from the portion of the optical element 71a near the edge of the light-receiving region 20C to the portion near the center, the traveling direction of the principal ray L3 can be deflected closer to the Z direction.

FIG. 18C shows an enlarged example of some of the plurality of optical elements 71 included in the optical element layer 70. More specifically, FIG. 18C shows an enlarged example of optical elements 71a, 71b, 71c, 71d, and 71e. Note that when the optical elements 71a, 71b, 71c, 71d, and 71e are not distinguished from each other, they are simply referred to as optical elements 71. Moreover, FIG. 18C shows a plurality of directions F from the edge of the light-receiving region 20C toward the center. As shown in the figure, the direction F extends radially from the edge of the light-receiving region 20C to the center. The optical elements 71a to 71e are arranged in that order at intervals along the X direction. Among them, the optical element 71c is arranged so as to overlap a position near the center of the light-receiving region 20C. The optical elements 71a and 71b are arranged along the direction F1, and the optical elements 71d and 71e are arranged along the direction F2. Note that when the directions F1 and F2 are not distinguished, they are simply referred to as direction F. The optical elements 71a, 71b, 71d, and 71e are each one optical element (first optical element) arranged so as to overlap a position away from the center of the light-receiving region 20C (position where the image height is high) in plan view. Among the optical elements 71a, 71b, 71d, and 71e, the optical elements 71a and 71e are located closest to the edge of the light-receiving region 20C. The optical elements 71b and 71d, which are arranged so as to overlap a position closer to the center of the light-receiving region 20C than the optical elements 71a and 71e (first optical element) in plan view, are each another optical element (second optical element). That is, the second optical element is an optical element located between the first optical element and the optical element 71 (third optical element) arranged so as to overlap a position near the center (center of image height) of the light-receiving region 20C.

As shown in FIG. 18C, in the optical elements 71a, 71b, 71c, 71d, and 71e, although the arrangement direction of the structures 72 is along the direction F (directions F1 and F2 in the present embodiment), the width, arrangement pitch, arrangement position, and the like of the structures 72 may be different. In this way, the width and arrangement position of the structures 72 included in the optical element 71 differ depending on the arrangement position of the optical element 71 in the optical element layer 70. The width, arrangement position, and the like of the structures 72 may be designed depending on the arrangement position of the optical element 71 in the optical element layer 70 and the angle of incidence of the principal ray.

As shown in FIG. 18C, in one optical element 71, for example, the optical element 71a, which is arranged so as to overlap a position away from the center of the light-receiving region 20C in plan view, the structures 72 are arranged along a direction from a portion of the optical element 71a near the edge of the light-receiving region 20C to a portion near the center. The structures 72 included in the optical element 71a are arranged along the direction F1. The density of the structures 72 in the optical element 71a in plan view is higher in a portion of the optical element 71a near the center of the light-receiving region 20C than in a portion near the edge. More specifically, the density of the structures 72 in the optical element 71a in plan view gradually increases from the portion of the optical element 71a near the edge of the light-receiving region 20C to the portion near the center (along the direction F1).

Such characteristics are also the same for the optical element 71 (second optical element, for example, the optical element 71b and the optical element 71d) arranged so as to overlap a position closer to the center of the light-receiving region 20C than the optical element 71a (first optical element) in plan view. However, when comparing the optical element 71a and the optical element 71b, in plan view, the density of the structures 72 in the portion of the optical element 71a near the edge (center) of the light-receiving region 20C is higher than the density of the structures 72 in the portion of the optical element 71b near the center of the region 20C. That is, the more the optical element 71 arranged to overlap a position closer to the edge of the light-receiving region 20C in plan view, the higher becomes the density of the structures 72 in the portion near the center of the light-receiving region 20C. The more the optical element 71 is arranged to overlap a position closer to the center of the light-receiving region 20C in plan view, the lower the density of the structures 72 in the portion near the center of the light-receiving region 20C. This is because the angle θ at which the principal ray is incident differs depending on the position of the optical element 71 in the optical element layer 70, and the required deflection angle also differs depending on the position of the optical element 71 in the optical element layer 70.

For example, the more the optical element 71 is arranged to overlap a position closer to the edge of the light-receiving region 20C in plan view, the larger becomes the angle θ between the incident principal ray and the Z direction. This is because, in order to deflect such a principal ray closer to the Z direction, it is necessary to increase the density of the structures 72 in a portion of the optical element 71 near the center of the light-receiving region 20C and to increase the deflection angle. For example, the more the optical element 71 is arranged to overlap a position closer to the center of the light-receiving region 20C in plan view, the smaller becomes the angle θ between the incident principal ray and the Z direction. In this case, since the angle at which the principal ray is deflected closer to the Z direction is small, the density gradient of the structures 72 may be made low in a portion of the optical element 71 near the center of the light-receiving region 20C. In this way, the more the optical element 71 is arranged to overlap a position closer to the edge of the light-receiving region 20C in plan view, the higher becomes the density of the structures 72 in the portion closer to the center of the light-receiving region 20C.

The above characteristics are also the same for the optical element 71e and the optical element 71d. In the above description, the optical element 71a may be replaced with the optical element 71e, the optical element 71b may be replaced with the optical element 71d, and the direction F1 may be replaced with the direction F2. The above-mentioned characteristics also apply to any (or all) other optical elements 71 arranged so as to overlap a position away from the center of the light-receiving region 20C in plan view and to the direction F corresponding to the optical element 71.

In the optical element 71c arranged so as to overlap a position near the center (center of image height) of the light-receiving region 20C, a plurality of structures 72 having the same width are evenly arranged along the directions F1 and F2.

### <Multilayer Filter>

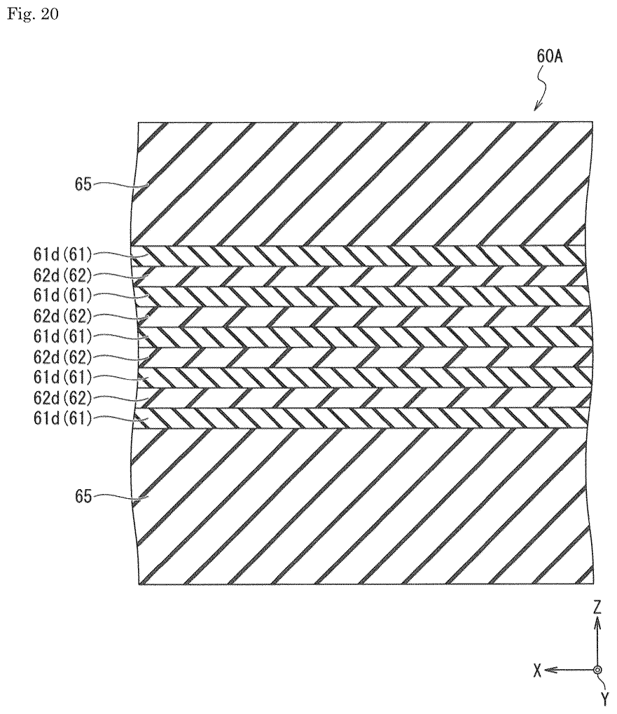

The light having passed through the optical element 71 enters the multilayer filter 60A. The multilayer filter 60A is a multilayer filter that has a stacked structure in which a high-refractive-index layer 61 and a low-refractive-index layer 62 are alternately stacked, and has a transmission spectrum specific to the stacked structure. More specifically, as shown in FIG. 20, the multilayer filter 60A has a stacked structure in which a high-refractive-index layer 61d, which is an example of the high-refractive-index layer 61, and a low-refractive-index layer 62d, which is an example of the low-refractive-index layer 62, are alternately stacked, and further has an insulating film 65 stacked on both sides of the stacked structure. The number of layers of the high-refractive-index layers 61 and the low-refractive-index layers 62 can be appropriately set according to the performance required for the multilayer filter 60A, and is not limited to the example shown in FIG. 20. The present embodiment will be described assuming that the multilayer filter 60A is an infrared-cut filter. The multilayer filter 60A is a reflective infrared-cut filter, and is a filter that reflects at least most of the infrared rays. The material constituting the high-refractive-index layer 61d may be, but not limited to, titanium oxide (TiO₂), for example. The material constituting the low-refractive-index layer 62d may be, but not limited to, silicon oxide (SiO₂), for example. The material constituting the insulating film 65 may be, but not limited to, silicon oxide (SiO₂), for example.

### <<Method of Manufacturing Light Detection Device>>

Hereinafter, a method of manufacturing the light detection device 1 will be described. First, a substrate including the support substrate 40 to the multilayer filter 60A is prepared using a known method. Then, a silicon nitride film, which is a material forming the structure 72, is formed on the exposed surface of the multilayer filter 60A. Thereafter, the structure 72 is formed using known lithography and etching techniques.

### <<Main Effects of Second Embodiment>>

The main effects of the second embodiment will be explained below. Also in the case of the light detection device 1 according to this second embodiment, effects similar to those of the light detection device 1 according to the first embodiment described above can be obtained.

More specifically, in the light detection device 1 according to the second embodiment of the present technology, the multilayer filter 60A is integrally stacked on the light detection device 1. Therefore, similarly to the case shown in FIG. 4E of the first embodiment, it is possible to suppress the light L4 from entering the pixel 3 located far away in plan view and suppress the region where flare occurs from widening.

The light detection device 1 according to the second embodiment of the present technology includes an optical element 71 having a plurality of structures 72 arranged at intervals in the width direction in plan view, and the density of the structures 72 in the optical element 71 (first optical element) in plan view is higher in a portion of the optical element 71 near the center of the light-receiving region 20C than in a portion near the edge. The principal ray that is obliquely incident on such an optical element 71 is deflected by the optical element 71 in a direction in which its traveling direction approaches the Z direction. Therefore, it is possible to suppress the principal ray from being incident on the multilayer filter 60A at an angle far from vertical. As a result, within the multilayer filter 60A, the optical path length of the principal rays (for example, principal rays L1 and L3) traveling obliquely is suppressed from becoming longer than the optical path length of the principal ray L2 traveling in the Z direction, and the principal rays L1 and L3 can be prevented from shifting significantly toward the shorter wavelength side. As a result, even if the light is oblique light, light that is originally designed to pass through the multilayer filter 60A, such as a part of red light, can be suppressed from being reflected by the multilayer filter 60A, and the deterioration of color reproducibility at positions of the image plane where the image height is high can be suppressed.

Furthermore, conventionally, when the principal rays L1 and L3 obliquely enter the multilayer filter 60A, they enter adjacent pixels 3 of different colors, potentially causing color mixture.

On the other hand, in the light detection device 1 according to the second embodiment of the present technology, even the principal ray traveling obliquely is suppressed from entering the multilayer filter 60A at an angle far from vertical. Therefore, it is possible to suppress the occurrence of color mixture due to light incident on adjacent pixels 3.

### Modified Examples of Second Embodiment

Hereinafter, modified examples of the second embodiment will be described.

### Modified Example 1

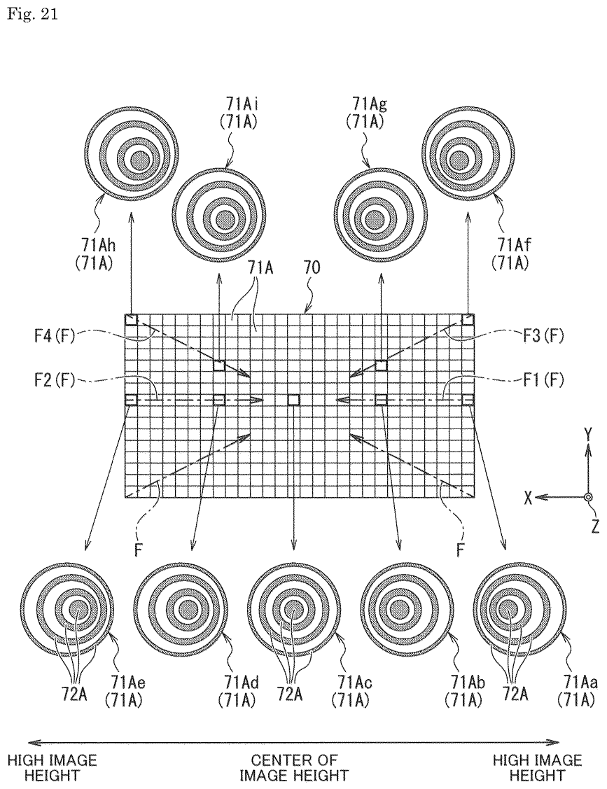

In the light detection device 1 according to the second embodiment, although one structure 72 included in one optical element 71 extends linearly in the longitudinal direction (direction intersecting the width direction) in plan view, the present technology is not limited thereto. In Modified Example 1 of the second embodiment shown in FIG. 21, one structure 72A included in one optical element 71A is continuous (connected) in the longitudinal direction.

The optical element layer 70 is formed by arranging a plurality of optical elements 71A in a two-dimensional array. FIG. 21 shows an enlarged example of some of the plurality of optical elements 71A included in the optical element layer 70. More specifically, optical elements 71Aa to 71Ai are shown in an enlarged manner. Note that when the optical elements 71Aa to 71Ai are not distinguished from each other, they are simply referred to as optical elements 71A. The optical element 71Ac is arranged so as to overlap a position near the center of the light-receiving region 20C. The optical elements 71Aa and 71Ab are arranged along the direction F1, and the optical elements 71Ad and 71Ae are arranged along the direction F2. Further, the optical elements 71Af and 71Ag are arranged along the direction F3, and the optical elements 71Ah and 71Ai are arranged along the direction F4. The optical elements 71Aa, 71Ab, 71Ad to 71Ai are optical elements (first optical elements) arranged so as to overlap a position away from the center of the light-receiving region 20C in plan view.

One optical element 71A has a plurality of structures 72A. One structure 72A is an annular body with continuous ends in the longitudinal direction (direction intersecting the width direction). More specifically, one structure 72A is an annular body having a circular outer edge and a circular inner edge in plan view. Hereinafter, the structure 72A will be described using as an example the optical element 71Ac (third optical element) arranged so as to overlap a position near the center of the light-receiving region 20C. The optical element 71Ac has three annular structures 72A having different diameters, and further includes one circular structure 72A provided at the center of the annular structures 72A. The plurality of structures 72A included in the optical element 71Ac are provided so that the centers of the ring and the circle coincide with each other without overlapping each other in plan view. Another annular structure 72A is provided so as to surround one annular structure 72A in plan view. An annular structure 72A is provided so as to surround the circular structure 72A in plan view. The structures 72A are arranged at intervals in the width direction in plan view.

Since the optical element 71Ac includes the annular structure 72A as described above, it functions as a lens that focuses the incident principal ray onto the photoelectric conversion unit 22. In Modified Example, since the refractive index decreases radially from the center to the edge of the optical element 71Ac in plan view, the principal ray is deflected so that the wavefront P becomes convex along the Z direction, although not shown. More specifically, the principal ray is deflected so that the wavefront P becomes convex toward the side of the optical element 71 opposite to the multilayer filter 60 side. In other words, the principal ray is deflected so that the wavefront P becomes convex toward the upstream side in the traveling direction. As a result, the width of the wavefront P becomes gradually narrower as the principal ray travels, and the light is focused inside the photoelectric conversion unit 22. In this way, the optical element 71c can function as a convex lens.

Next, one optical element 71A (first optical element) arranged so as to overlap a position away from the center of the light-receiving region 20C in plan view will be described, taking, for example, the optical element 71Aa as an example. The optical elements 71Aa differ from the optical elements 71Ac in that the positions of the centers of the annular and circular structures 72A do not coincide, and the optical elements 71Aa are arranged along the direction (direction F1) from the portion of the optical element 71Aa near the edge of the light-receiving region 20C to the portion near the center. The structures 72A are arranged at intervals from each other in the width direction in plan view at least along a direction from a portion of the optical element 71Aa near the edge of the light-receiving region 20C to a portion near the center.

The density of the structures 72A in the optical element 71Aa in plan view is higher in a portion of the optical element 71Aa near the center of the light-receiving region 20C than in a portion near the edge. More specifically, the density of the structures 72A in the optical element 71Aa in plan view gradually increases from the portion of the optical element 71Aa near the edge of the light-receiving region 20C to the portion near the center (along the direction F1). With such a configuration, the optical element 71Aa can deflect the traveling direction of the obliquely incident principal ray L3 closer to the Z direction. Note that the above-described characteristics of the optical element 71Aa are also the same for the other optical element 71A arranged so as to overlap a position away from the center of the light-receiving region 20C in plan view.

Incidentally, gradually increasing the density of the structures 72A in one optical element 71Aa in plan view along the direction F1 can be achieved, but not limited to, for example, by densely arranging the centers of the annular and circular structures 72A in one optical element 71Aa along the direction (direction F1) from the portion of the optical element 71Aa near the edge of the light-receiving region 20C to the portion near the center. Since the optical element 71Aa has the annular structure 72A as described above, it can function as a convex lens that focuses the incident principal ray on the photoelectric conversion unit 22, similarly to the optical element 71Ac.

The above-mentioned characteristics are also the same for the optical element 71A (second optical element, for example, optical element 71Ab) arranged so as to overlap a position closer to the center of the light-receiving region 20C than the optical element 71Aa (first optical element). However, when comparing the optical element 71Aa and the optical element 71Ab, in plan view, the density of the structures 72A in the portion of the optical element 71Aa near the edge (center) of the light-receiving region 20C is higher than the density of the structures 72A in the portion of the optical element 71Ab near the center of the light-receiving region 20C. In other words, the more the optical element 71A is arranged to overlap a position closer to the edge of the light-receiving region 20C in plan view, the higher becomes the density of the structures 72A in the portion near the center of the light-receiving region 20C. The more the optical element 71A is arranged to overlap a position closer to the center of the light-receiving region 20C in plan view, the lower becomes the density of the structures 72A in the portion near the center of the light-receiving region 20C. This can be achieved by arranging the centers of the annular and circular structure 72A along the direction F1 more sparsely in a portion of the optical element 71Ab near the center of the light-receiving region 20C than in a portion of the optical element 71Aa near the center of the light-receiving region 20C.

The main effects of Modified Example 1 of the second embodiment will be described below. Also in the case of the light detection device 1 according to Modified Example 1 of the second embodiment, effects similar to those of the light detection device 1 according to the second embodiment described above can be obtained.

Moreover, since the light detection device 1 according to Modified Example 1 of the second embodiment of the present technology has the annular structure 72A, the refractive index changes radially, and the principal ray is deflected so that the wavefront P becomes convex. As a result, the width of the wavefront P becomes gradually narrower as the principal ray travels, and the light is focused inside the photoelectric conversion unit 22. In this way, the sensitivity of the light detection device 1 is improved.

### Modified Example 2

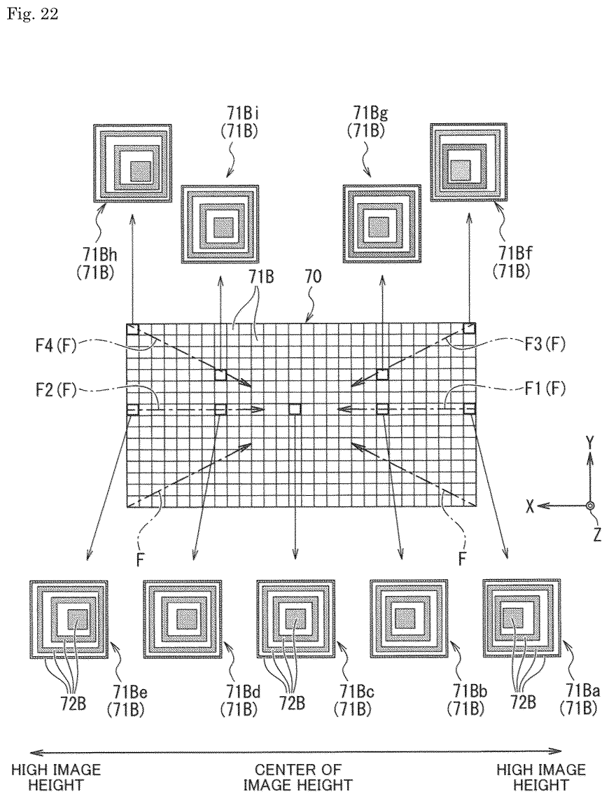

In the light detection device 1 according to the second embodiment, although one structure 72 included in one optical element 71 extends linearly in the longitudinal direction (direction intersecting the width direction) in plan view, the present technology is not limited thereto. In Modified Example 2 of the second embodiment shown in FIG. 22, one structure 72B included in one optical element 71B is continuous in the longitudinal direction.

In Modified Example 1 of the second embodiment, one structure 72A is an annular body having a circular outer edge and a circular inner edge in plan view, but the present technology is not limited thereto. In Modified Example 2 of the second embodiment shown in FIG. 22, one structure 72B is a rectangular annular body having a rectangular outer edge and a rectangular inner edge in plan view.

The optical element layer 70 is formed by arranging a plurality of optical elements 71B in a two-dimensional array. FIG. 22 shows an enlarged example of some of the plurality of optical elements 71B included in the optical element layer 70. More specifically, optical elements 71Ba to 71Bi are shown in an enlarged manner. Note that when the optical elements 71Ba to 71Bi are not distinguished from each other, they are simply referred to as optical elements 71B. The optical element 71Bc is arranged so as to overlap a position near the center of the light-receiving region 20C. The optical elements 71Ba and 71Bb are arranged along the direction F1, and the optical elements 71Bd and 71Be are arranged along the direction F2. Further, the optical elements 71Bf and 71Bg are arranged along the direction F3, and the optical elements 71Bh and 71Bi are arranged along the direction F4. The optical elements 71Ba, 71Bb, 71Bd to 71Bi are optical elements (first optical elements) arranged so as to overlap a position away from the center of the light-receiving region 20C in plan view.

One optical element 71B has a plurality of structures 72B. One structure 72B is an annular body that is continuous in the longitudinal direction (direction intersecting the width direction). More specifically, one structure 72B is a rectangular annular body having a rectangular outer edge and a rectangular inner edge in plan view. In addition, although the structure 72B is square in FIG. 22, it is not limited to this, and may be rectangular. Hereinafter, the structure 72B will be described using the optical element 71Bc (third optical element) arranged so as to overlap a position near the center of the light-receiving region 20C as an example. The optical element 71Bc has three annular structures 72B with different dimensions, and further includes one rectangular structure 72B provided at the center of the annular structures 72B. The plurality of structures 72B included in the optical element 71Bc are provided so that the centers of the annular body and the rectangular body coincide with each other in plan view without overlapping each other. Another annular structure 72B is provided so as to surround one annular structure 72B in plan view. An annular structure 72B is provided to surround the rectangular structure 72B in plan view. The structures 72B are arranged at intervals from each other in the width direction in plan view. Since the optical element 71Bc has the annular structure 72B as described above, it functions as a lens that focuses the incident principal ray on the photoelectric conversion unit 22, as in the case of Modified Example 1 of the second embodiment.

Next, one optical element 71B (first optical element) arranged so as to overlap a position away from the center of the light-receiving region 20C in plan view will be described, taking, for example, the optical element 71Ba as an example. The optical elements 71Ba differ from the optical elements 71Bc in that the positions of the centers of the annular and circular structures 72B do not coincide, and the optical elements 71Ba are arranged along the direction (direction F1) from the portion of the optical element 71Ba near the edge of the light-receiving region 20C to the portion near the center. The structures 72B are arranged at intervals from each other in the width direction in plan view at least along a direction from a portion of the optical element 71Ba near the edge of the light-receiving region 20C to a portion near the center.

The density of the structures 72B in the optical element 71Ba in plan view is higher in a portion of the optical element 71Ba near the center of the light-receiving region 20C than in a portion near the edge. More specifically, the density of the structures 72B in the optical element 71Ba in plan view gradually increases from the portion of the optical element 71Ba near the edge of the light-receiving region 20C to the portion near the center (along the direction F1). With such a configuration, the optical element 71Ba can deflect the traveling direction of the obliquely incident principal ray L3 closer to the Z direction. Note that the above-mentioned characteristics are also the same for the other optical element 71B arranged so as to overlap a position away from the center of the light-receiving region 20C in plan view.

Incidentally, gradually increasing the density of the structures 72B in one optical element 71Ba in plan view along the direction F1 can be achieved, but not limited to, for example, by densely arranging the centers of the annular and rectangular structures 72B in one optical element 71Ba along the direction (direction F1) from the portion of the optical element 71Ba near the edge of the light-receiving region 20C to the portion near the center. Since the optical element 71Ba has the annular structure 72B as described above, it can function as a convex lens that focuses the incident principal ray on the photoelectric conversion unit 22, similarly to the optical element 71Bc.

The above-mentioned characteristics are also the same for the optical element 71B (second optical element, for example, optical element 71Bb) arranged so as to overlap a position closer to the center of the light-receiving region 20C than the optical element 71Ba (first optical element). However, when comparing the optical element 71Ba and the optical element 71Bb, in plan view, the density of the structures 72B in the portion of the optical element 71Ba near the edge (center) of the light-receiving region 20C is higher than the density of the structures 72B in the portion of the optical element 71Bb near the center of the light-receiving region 20C. That is, the more the optical element 71B is arranged to overlap a position closer to the edge of the light-receiving region 20C in plan view, the higher becomes the density of the structures 72B in the portion near the center of the light-receiving region 20C. The more the optical element 71B is arranged to overlap a position closer to the center of the light-receiving region 20C in plan view, the lower becomes the density of the structures 72B in the portion near the center of the light-receiving region 20C. This can be achieved by arranging the centers of the annular and circular structure 72B along the direction F1 more sparsely in a portion of the optical element 71Bb near the center of the light-receiving region 20C than in a portion of the optical element 71Ba near the center of the light-receiving region 20C.

The main effects of Modified Example 2 of the second embodiment will be described below. Also in the case of the light detection device 1 according to Modified Example 2 of the second embodiment, effects similar to those of the light detection device 1 according to the second embodiment described above can be obtained. Also in the case of the light detection device 1 according to Modified Example 2 of the second embodiment, effects similar to those of the light detection device 1 according to Modified Example 1 of the second embodiment described above can be obtained.

### Modified Example 3

In the light detection device 1 according to Modified Example 3 of the second embodiment, the structure of the multilayer filter is different. The multilayer filter 60B included in the light detection device 1 according to Modified Example 3 of the second embodiment will be described below.

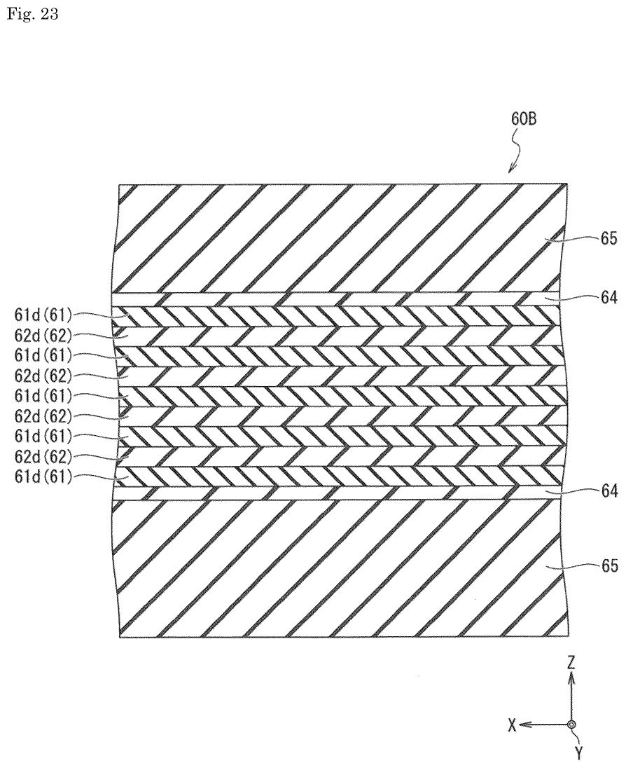

As shown in FIG. 23, the multilayer filter 60B has a stacked structure in which a high-refractive-index layer 61 and a low-refractive-index layer 62 are alternately stacked, an anti-reflection film 64 stacked on both sides of the stacked structure, and an insulating film 65 stacked on the anti-reflection film 64. The anti-reflection film 64 is made of, but not limited to, for example, silicon nitride. Further, the thickness of the anti-reflection film 64 may be appropriately set depending on the wavelength to be canceled. The thickness d of the anti-reflection film 64 is determined by d=λ/(4*n). Here, λ is the center wavelength of the incident light, and n is the refractive index of the material forming the anti-reflection film 64.

The main effects of Modified Example 3 of the second embodiment will be described below. Also in the case of the light detection device 1 according to Modified Example 3 of the second embodiment of the present technology, effects similar to those of the light detection device 1 according to the second embodiment of the present technology can be obtained.

Furthermore, conventionally, the spectral characteristics of multilayer filters have been such that the transmittance changes in a wavy manner with respect to wavelength. Such changes in transmittance were referred to as ripples (vibrations). Ripples occur, for example, when the principal ray is reflected and light components interfere and strengthen and weaken each other. When ripples occur in the spectral characteristics of the multilayer filter, the transmittance of the principal ray changes depending on the wavelength, which may deteriorate the color reproducibility of the obtained image. More specifically, in the obtained image, there were cases where color corresponding to wavelengths with low transmittance became lighter and color corresponding to wavelengths with high transmittance became darker.

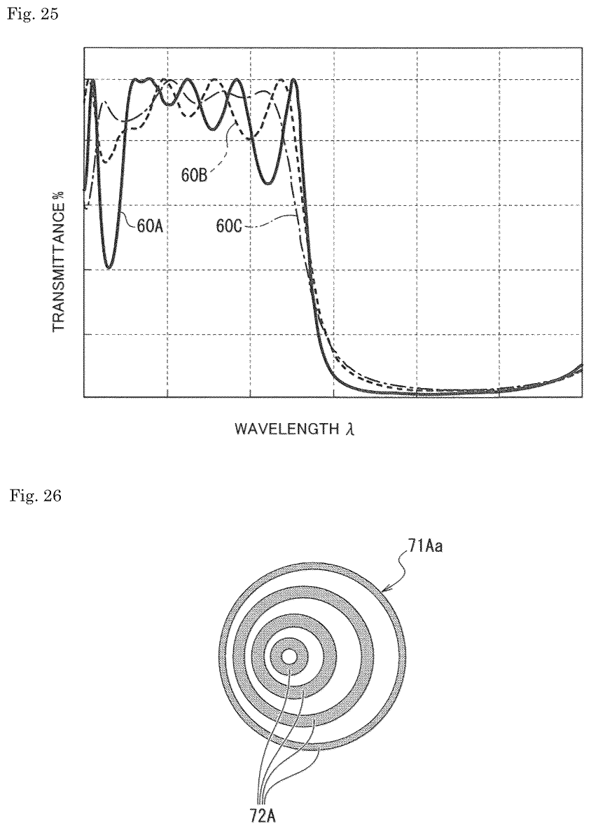

In contrast, since the multilayer filter 60B of the light detection device 1 according to Modified Example 3 of the second embodiment of the present technology has the anti-reflection film 64, it is possible to suppress the reflection of light itself. Therefore, as shown in FIG. 25, the multilayer filter 60A can prevent light from interfering and strengthening and weakening each other at specific wavelengths. In this way, deterioration of color reproducibility in the obtained image can be further suppressed.

### Modified Example 4

In the light detection device 1 according to Modified Example 4 of the second embodiment, the structure of the multilayer filter is different. The multilayer filter 60C included in the light detection device 1 according to Modified Example 4 of the second embodiment will be described below.

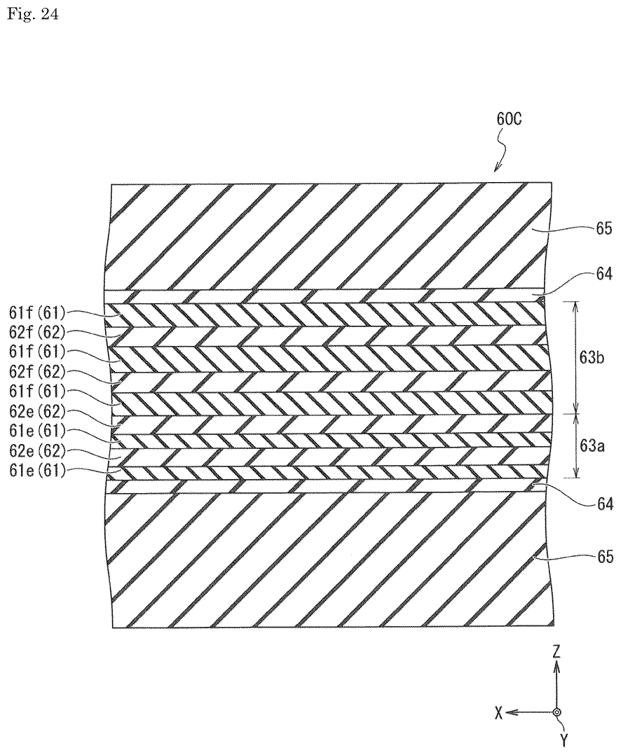

As shown in FIG. 24, the multilayer filter 60C has a stacked structure in which a high-refractive-index layer 61 and a low-refractive-index layer 62 are alternately stacked, an anti-reflection film 64 stacked on both sides of the stacked structure, and an insulating film 65 stacked on the anti-reflection film 64. The stacked structure includes a first stacked structure 63a and a second stacked structure 63b stacked along the Z direction. The first stacked structure 63a has a stacked structure in which a high-refractive-index layer 61e and a low-refractive-index layer 62e are alternately stacked, and the second stacked structure 63b has a stacked structure in which a high-refractive-index layer 61f and a low-refractive-index layer 62f are alternately stacked. The first stacked structure 63a and the second stacked structure 63b have different stacking pitches between high-refractive-index layers and low-refractive-index layers. More specifically, the first stacked structure 63a and the second stacked structure 63b differ in the thickness of at least one of the high-refractive-index layer and the low-refractive-index layer.

Also in the case of the light detection device 1 according to Modified Example 4 of the second embodiment of the present technology, effects similar to those of the light detection device 1 according to the second embodiment of the present technology can be obtained.

Moreover, since the multilayer filter 60C of the light detection device 1 according to Modified Example 4 of the second embodiment of the present technology has a plurality of stacked structures with different stacking pitches, it becomes possible to construct a stacked structure in which ripples are less likely to occur for light in different bands. Therefore, as shown in FIG. 25, the multilayer filter 60B can further prevent light from interfering and strengthening and weakening each other at specific wavelengths. In this way, deterioration of color reproducibility in the obtained image can be further suppressed.

### Modified Example 5

In Modified Example 1 of the second embodiment, one optical element 71A had an annular and circular structure 72A, but the present technology is not limited thereto. In Modified Example 5 of the second embodiment shown in FIG. 26, one optical element 71A may include only an annular structure 72A.

Also in the case of the light detection device 1 according to Modified Example 5 of the second embodiment of the present technology, effects similar to those of the light detection device 1 according to the second embodiment of the present technology can be obtained. Also in the case of the light detection device 1 according to Modified Example 5 of the second embodiment of the present technology, effects similar to those of the light detection device 1 according to Modified Example 1 of the second embodiment of the present technology can be obtained.

Although not shown in the figure, in Modified Example 2 of the second embodiment, one optical element 71B may similarly include only the annular structure 72B.

### Modified Example 6

In the light detection device 1 according to the second embodiment, one structure 72 included in one optical element 71 has a plate-like shape and extends linearly in the longitudinal direction in plan view, but the technology is not limited thereto. In Modified Example 6 of the second embodiment, although not shown in the figure, one structure 72 may have a pillar shape extending in the Z direction. Note that the cross-sectional shape of the pillar in the horizontal direction is not particularly limited.

Also in the case of the light detection device 1 according to Modified Example 6 of the second embodiment of the present technology, effects similar to those of the light detection device 1 according to the second embodiment of the present technology can be obtained.

### Third Embodiment

Application examples will be explained below.

### <1. Application Examples to Electronic Devices>

First, an electronic device 100 shown in FIG. 27 will be described. The electronic device 100 includes a solid-state imaging device 101, an optical lens 102, a shutter device 103, a drive circuit 104, and a signal processing circuit 105. The electronic device 100 is, but not limited to, for example, an electronic device such as a camera. The electronic device 100 includes the above-described light detection device 1 as the solid-state imaging device 101.

The optical lens (optical system) 102 forms an image of image light (incident light 106) from the subject onto the imaging surface of the solid-state imaging device 101. As a result, signal charges are accumulated within the solid-state imaging device 101 for a certain period of time.

The shutter device 103 controls the light irradiation period and the light blocking period of the solid-state imaging device 101. The drive circuit 104 supplies drive signals that control the transfer operation of the solid-state imaging device 101 and the shutter operation of the shutter device 103. Signal transfer of the solid-state imaging device 101 is performed by a drive signal (timing signal) supplied from the drive circuit 104. The signal processing circuit 105 performs various types of signal processing on signals (pixel signals) output from the solid-state imaging device 101. An image signal having been subjected to signal processing is stored in a storage medium such as a memory or output to a monitor.

With such a configuration, in the electronic device 100, deterioration of color reproducibility in the solid-state imaging device 101 is suppressed, so that the image quality of the video signal can be improved.

Note that the electronic device 100 is not limited to a camera, and may be another electronic device. For example, it may be a camera module for mobile devices such as a mobile phone, or an imaging device such as a fingerprint sensor. The fingerprint sensor may include a light source, emit light toward the finger, and receive the reflected light.

The electronic device 100 can include, as the solid-state imaging device 101, the light detection device 1 according to any one of the first embodiment, the second embodiment, and the modified examples of these embodiments, or the light detection device 1 according to a combination of at least two of the first embodiment, the second embodiment, and the modified examples of these embodiments.

In conventional electronic devices, an infrared-absorbing member may be provided between the solid-state imaging device 101 and the optical lens 102 and on the incident light side of the optical lens 102. By providing a plurality of infrared-absorbing members in the optical path, the infrared rays are repeatedly transmitted and reflected, thereby attenuating the infrared rays. However, by providing a plurality of infrared-absorbing members, manufacturing costs have increased.

In contrast, in the electronic device 100 to which the present technology is applied, an infrared-cut filter (multilayer filter) is not provided between the solid-state imaging device 101 and the optical lens 102 and on the incident light side of the optical lens 102, but the infrared-cut filter is provided only in the solid-state imaging device 101. Therefore, an increase in manufacturing costs can be suppressed.

### 2. Example of Application to Mobile Object

The technique according to the present disclosure (the present technique) can be applied to various products. For example, the technology according to the present disclosure may be achieved as a device equipped in any type of mobile object such as an automobile, an electric vehicle, a hybrid electric vehicle, a motorcycle, a bicycle, a personal mobility device, an airplane, a drone, a ship, and a robot.

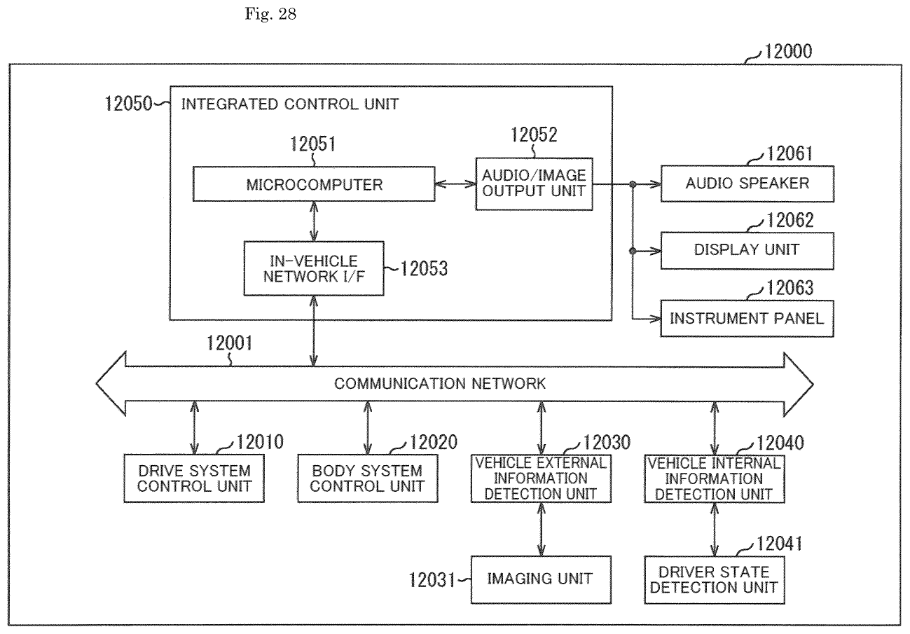

FIG. 28 is a block diagram showing a schematic configuration example of a vehicle control system, which is an example of a mobile object control system to which the technique according to the present disclosure can be applied.

The vehicle control system 12000 includes a plurality of electronic control units connected thereto via a communication network 12001. In the example shown in FIG. 28, the vehicle control system 12000 includes a drive system control unit 12010, a body system control unit 12020, a vehicle external information detection unit 12030, a vehicle internal information detection unit 12040, and an integrated control unit 12050. In addition, as a functional configuration of the integrated control unit 12050, a microcomputer 12051, an audio/image output unit 12052, and an in-vehicle network interface (I/F) 12053 are shown.

The drive system control unit 12010 controls an operation of an apparatus related to a drive system of a vehicle according to various programs. For example, the drive system control unit 12010 functions as a driving force generator for generating a driving force of a vehicle such as an internal combustion engine or a driving motor, a driving force transmission mechanism for transmitting a driving force to wheels, a steering mechanism for adjusting a turning angle of a vehicle, and a control apparatus such as a braking apparatus that generates a braking force of a vehicle.

The body system control unit 12020 controls operations of various devices mounted in the vehicle body according to various programs. For example, the body system control unit 12020 functions as a control device of a keyless entry system, a smart key system, a power window device, or various lamps such as a headlamp, a back lamp, a brake lamp, a turn signal, and a fog lamp. In this case, radio waves transmitted from a portable device that substitutes for a key or signals of various switches may be input to the body system control unit 12020. The body system control unit 12020 receives inputs of the radio waves or signals and controls a door lock device, a power window device, and a lamp of the vehicle.

The vehicle external information detection unit 12030 detects information on the outside of the vehicle having the vehicle control system 12000 mounted thereon. For example, an imaging unit 12031 is connected to the vehicle external information detection unit 12030. The vehicle external information detection unit 12030 causes the imaging unit 12031 to capture an image of the outside of the vehicle and receives the captured image. The vehicle external information detection unit 12030 may perform object detection processing or distance detection processing for persons, cars, obstacles, signs, and letters on the road on the basis of the received image.

The imaging unit 12031 is an optical sensor that receives light and outputs an electrical signal according to the amount of the received light. The imaging unit 12031 can also output the electrical signal as an image or distance measurement information. The light received by the imaging unit 12031 may be visible light or invisible light such as infrared light.

The vehicle internal information detection unit 12040 detects information on the inside of the vehicle. For example, a driver state detection unit 12041 that detects a driver's state is connected to the vehicle internal information detection unit 12040. The driver state detection unit 12041 includes, for example, a camera that captures an image of a driver, and the vehicle internal information detection unit 12040 may calculate the degree of fatigue or concentration of the driver or may determine whether or not the driver is dozing on the basis of detection information input from the driver state detection unit 12041.

The microcomputer 12051 can calculate a control target value of the driving force generation device, the steering mechanism, or the braking device on the basis of the information on the outside or the inside of the vehicle acquired by the vehicle external information detection unit 12030 or the vehicle internal information detection unit 12040 and output a control command to the drive system control unit 12010. For example, the microcomputer 12051 can perform cooperative control for the purpose of obtaining functions of an Advanced Driver Assistance System (ADAS) including collision avoidance or impact mitigation of a vehicle, following traveling based on inter-vehicle distance, vehicle speed maintenance driving, vehicle collision warning, vehicle lane deviation warning, or the like.

The microcomputer 12051 can perform cooperative control for the purpose of automated driving or the like in which autonomous travel is performed without depending on operations of the driver, by controlling the driving force generator, the steering mechanism, or the braking device and the like on the basis of information about the surroundings of the vehicle, the information being acquired by the vehicle external information detection unit 12030 or the vehicle internal information detection unit 12040.

The microcomputer 12051 can output a control command to the body system control unit 12020 based on the information acquired by the vehicle external information detection unit 12030 outside the vehicle. For example, the microcomputer 12051 can perform cooperative control for the purpose of preventing glare, such as switching from a high beam to a low beam, by controlling the headlamp according to the position of a preceding vehicle or an oncoming vehicle detected by the vehicle external information detection unit 12030.

The audio/image output unit 12052 transmits an output signal of at least one of sound and an image to an output device capable of visually or audibly notifying a passenger or the outside of the vehicle of information. In the example shown in FIG. 28, as such an output device, an audio speaker 12061, a display unit 12062 and an instrument panel 12063 are shown. The display unit 12062 may include, for example, at least one of an onboard display and a head-up display.

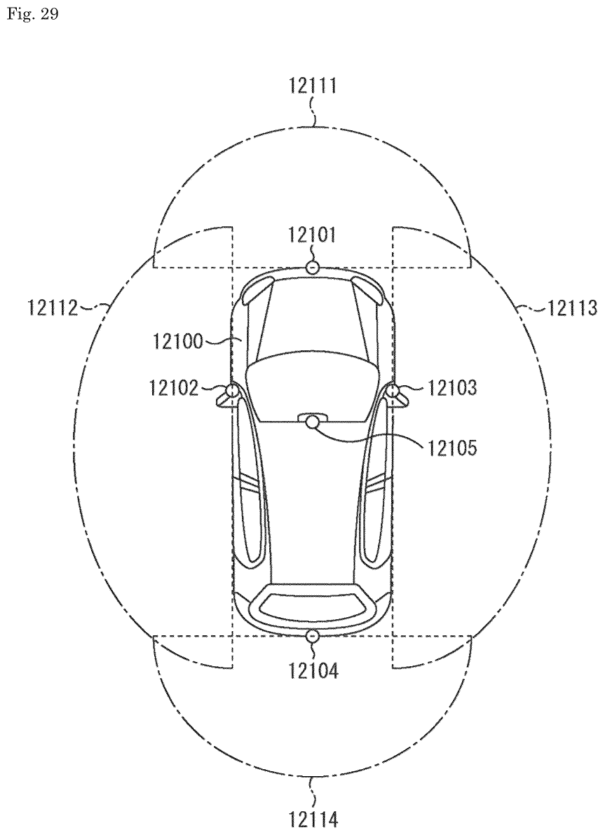

FIG. 29 is a diagram showing an example of an installation position of the imaging unit 12031.

In FIG. 29, a vehicle 12100 includes imaging units 12101, 12102, 12103, 12104, and 12105 as the imaging unit 12031.

The imaging units 12101, 12102, 12103, 12104, and 12105 are provided at positions such as a front nose, side-view mirrors, a rear bumper, a back door, and an upper portion of a windshield in a vehicle interior of the vehicle 12100, for example. The imaging unit 12101 provided on the front nose and the imaging unit 12105 provided in the upper portion of the windshield in the vehicle interior mainly acquire images of the front of the vehicle 12100. The imaging units 12102 and 12103 provided on the side-view mirrors mainly acquire images of a lateral side of the vehicle 12100. The imaging unit 12104 provided on the rear bumper or the back door mainly acquires images of the rear of the vehicle 12100. Front view images acquired by the imaging units 12101 and 12105 are mainly used for detection of preceding vehicles, pedestrians, obstacles, traffic lights, traffic signs, lanes, and the like.

Here, FIG. 29 shows an example of imaging ranges of the imaging units 12101 to 12104. An imaging range 12111 indicates an imaging range of the imaging unit 12101 provided at the front nose, imaging ranges 12112 and 12113 respectively indicate the imaging ranges of the imaging units 12102 and 12103 provided at the side-view mirrors, and an imaging range 12114 indicates the imaging range of the imaging unit 12104 provided at the rear bumper or the back door. For example, a bird's-eye view image of the vehicle 12100 as viewed from above can be obtained by superimposing pieces of image data captured by the imaging units 12101 to 12104.

At least one of the imaging units 12101 to 12104 may have a function for obtaining distance information. For example, at least one of the imaging units 12101 to 12104 may be a stereo camera constituted by a plurality of imaging elements or may be an imaging element that has pixels for phase difference detection.

For example, the microcomputer 12051 can extract, particularly, the closest three-dimensional object on a path along which the vehicle 12100 is traveling, which is a three-dimensional object traveling at a predetermined speed (for example, 0 km/h or higher) in the substantially same direction as the vehicle 12100, as a vehicle ahead by acquiring a distance to each three-dimensional object in the imaging ranges 12111 to 12114 and a temporal change of this distance (a relative speed with respect to the vehicle 12100) on the basis of the distance information obtained from the imaging units 12101 to 12104. Furthermore, the microcomputer 12051 can set an inter-vehicle distance to be secured from a vehicle ahead in advance with respect to the vehicle ahead and can perform automated brake control (also including following stop control) or automated acceleration control (also including following start control). In this way, cooperative control can be performed for the purpose of automated traveling or the like in which a vehicle automatedly travels without the operations of the driver.

For example, the microcomputer 12051 can classify and extract three-dimensional data regarding three-dimensional objects into two-wheeled vehicles, normal vehicles, large vehicles, pedestrians, and other three-dimensional objects such as electric poles based on distance information obtained from the imaging units 12101 to 12104 and can use the three-dimensional data to perform automated avoidance of obstacles. For example, the microcomputer 12051 differentiates surrounding obstacles of the vehicle 12100 into obstacles which can be viewed by the driver of the vehicle 12100 and obstacles which are difficult to view. Then, the microcomputer 12051 determines a collision risk indicating the degree of risk of collision with each obstacle, and when the collision risk is equal to or higher than a set value and there is a possibility of collision, an alarm is output to the driver through the audio speaker 12061 or the display unit 12062, forced deceleration or avoidance steering is performed through the drive system control unit 12010, and thus it is possible to perform driving support for collision avoidance.

At least one of the imaging units 12101 to 12104 may be an infrared camera that detects infrared rays. For example, the microcomputer 12051 can recognize a pedestrian by determining whether there is a pedestrian in the captured image of the imaging units 12101 to 12104. Such pedestrian recognition is performed by, for example, a procedure in which feature points in the captured images of the imaging units 12101 to 12104 as infrared cameras are extracted and a procedure in which pattern matching processing is performed on a series of feature points indicating an outline of an object to determine whether or not the object is a pedestrian. When the microcomputer 12051 determines that there is a pedestrian in the captured images of the imaging units 12101 to 12104 and the pedestrian is recognized, the audio/image output unit 12052 controls the display unit 12062 so that a square contour line for emphasis is superimposed and displayed with the recognized pedestrian. The audio/image output unit 12052 may control the display unit 12062 so that an icon indicating a pedestrian or the like is displayed at a desired position.

An example of the vehicle control system to which the technology according to the present disclosure can be applied has been described above. The technology according to the present disclosure can be applied to the imaging unit 12031 within the configuration described above. Specifically, the light detection device 1 shown in FIG. 4A and the light detection device 1 shown in FIG. 18B can be applied to the imaging unit 12031. By applying the technology according to the present disclosure to the imaging unit 12031, it is possible to obtain a captured image in which deterioration in color reproducibility is suppressed, thereby making it possible to reduce driver fatigue.

### 3. Example of Application to Endoscopic Surgery System

The technique according to the present disclosure (the present technique) can be applied to various products. For example, the technique according to the present disclosure may be applied to an endoscopic surgery system.

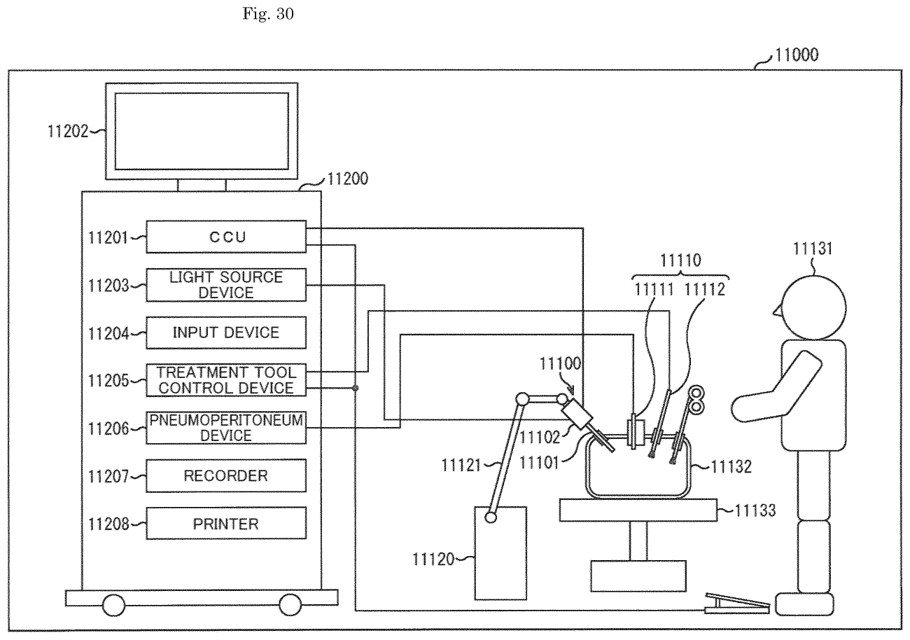

FIG. 30 shows an example of a schematic configuration of an endoscope surgery system to which the technique according to the present disclosure (the present technique) is applied.

FIG. 30 shows a state where an operator (doctor) 11131 is performing a surgical operation on a patient 11132 on a patient bed 11133 by using the endoscopic surgery system 11000. As shown in the figure, the endoscopic surgery system 11000 includes an endoscope 11100, other surgical instruments 11110 such as a pneumoperitoneum tube 11111 and an energized treatment tool 11112, a support arm device 11120 that supports the endoscope 11100, and a cart 11200 equipped with various devices for endoscopic surgery.

The endoscope 11100 includes a lens barrel 11101 of which a region having a predetermined length from a tip thereof is inserted into a body cavity of the patient 11132, and a camera head 11102 connected to a base end of the lens barrel 11101. In the shown example, the endoscope 11100 configured as a so-called rigid endoscope having the rigid lens barrel 11101 is shown, but the endoscope 11100 may be configured as a so-called flexible endoscope having a flexible lens barrel.

The distal end of the lens barrel 11101 is provided with an opening into which an objective lens is fitted. A light source device 11203 is connected to the endoscope 11100, light generated by the light source device 11203 is guided to the distal end of the lens barrel 11101 by a light guide extended to the inside of the lens barrel 11101, and the light is radiated toward an observation target in the body cavity of the patient 11132 through the objective lens. The endoscope 11100 may be a direct-viewing endoscope, an oblique-viewing endoscope, or a side-viewing endoscope.

An optical system and an image sensor are provided inside the camera head 11102, and the reflected light (observation light) from the observation target is focused on the image sensor by the optical system. The image sensor photoelectrically converts the observation light, and an electrical signal corresponding to the observation light, that is, an image signal corresponding to an observation image is formed. The image signal is transmitted to a Camera Control Unit (CCU) 11201 as RAW data.

The CCU 11201 is configured of a Central Processing Unit (CPU), a Graphics Processing Unit (GPU), and the like and comprehensively controls the operation of the endoscope 11100 and a display device 11202. In addition, the CCU 11201 receives an image signal from the camera head 11102 and performs various types of image processing for displaying an image based on the image signal, for example, development processing (demosaic processing) on the image signal.

The display device 11202 displays the image based on the image signal subjected to the image processing by the CCU 11201 under the control of the CCU 11201.

The light source device 11203 is constituted of, for example, a light source such as an LED (Light Emitting Diode) and supplies the endoscope 11100 with irradiation light when photographing a surgical site or the like.

An input device 11204 is an input interface for the endoscopic surgery system 11000. The user can input various types of information or instructions to the endoscopic surgery system 11000 via the input device 11204. For example, the user inputs an instruction to change imaging conditions (a type of applied light, a magnification, a focal length, or the like) of the endoscope 11100 or other instructions.

A treatment tool control device 11205 controls driving of the energized treatment tool 11112 for cauterization or incision of a tissue, sealing of blood vessel, or the like. A pneumoperitoneum device 11206 sends a gas into the body cavity of the patient 11132 via the pneumoperitoneum tube 11111 in order to inflate the body cavity for the purpose of securing a field of view using the endoscope 11100 and a working space of the surgeon. A recorder 11207 is a device capable of recording various types of information on surgery. A printer 11208 is a device capable of printing various types of information on surgery in various formats such as text, images, and graphs.

The light source device 11203 that supplies applied light for capturing the image of the surgical site to the endoscope 11100 can be configured of, for example, an LED, a laser light source, or a white light source configured of a combination thereof. When a white light source is formed by a combination of RGB laser light sources, it is possible to control the output intensity and the output timing of each color (each wavelength) with high accuracy, and thus the light source device 11203 can adjust the white balance of the captured image. In this case, laser light from each of the respective RGB laser light sources is applied to the observation target in a time division manner, and the driving of the image sensor of the camera head 11102 is controlled in synchronization with the light application timing so that images corresponding to respective RGBs can be captured in a time division manner. According to this method, it is possible to obtain a color image without providing a color filter in the image sensor.

Driving of the light source device 11203 may be controlled so that an intensity of output light is changed at predetermined time intervals. The driving of the image sensor of the camera head 11102 is controlled in synchronization with a timing of changing the intensity of the light, and images are acquired in a time division manner and combined, such that an image having a high dynamic range without so-called blackout and whiteout can be generated.

The light source device 11203 may have a configuration in which light in a predetermined wavelength band corresponding to special light observation can be supplied. In the special light observation, for example, by emitting light in a band narrower than that of radiation light (that is, white light) during normal observation using wavelength dependence of light absorption in a body tissue, so-called narrow band light observation (Narrow Band Imaging) is performed in which a predetermined tissue such as a blood vessel in a mucous membrane surface layer is imaged with a high contrast. Alternatively, in the special light observation, fluorescence observation may be performed to obtain an image by fluorescence generated by emitting excitation light. The fluorescence observation can be performed by emitting excitation light to a body tissue and observing fluorescence from the body tissue (autofluorescence observation), or locally injecting a reagent such as indocyanine green (ICG) to a body tissue and emitting excitation light corresponding to a fluorescence wavelength of the reagent to the body tissue to obtain a fluorescence image. The light source device 11203 may be configured such that narrow band light and/or excitation light corresponding to such special light observation can be supplied.

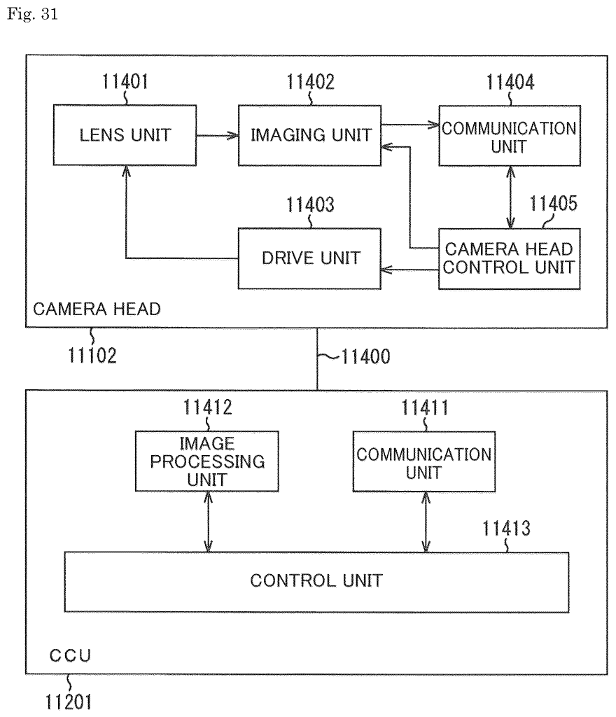

FIG. 31 is a block diagram showing an example of a functional configuration of the camera head 11102 and the CCU 11201 shown in FIG. 30.

The camera head 11102 includes a lens unit 11401, an imaging unit 11402, a drive unit 11403, a communication unit 11404, and a camera head control unit 11405. The CCU 11201 has a communication unit 11411, an image processing unit 11412, and a control unit 11413. The camera head 11102 and the CCU 11201 are communicatively connected to each other by a transmission cable 11400.

The lens unit 11401 is an optical system provided in a connection portion for connection to the lens barrel 11101. Observation light taken from a tip of the lens barrel 11101 is guided to the camera head 11102 and is incident on the lens unit 11401. The lens unit 11401 is configured in combination of a plurality of lenses including a zoom lens and a focus lens.

The imaging unit 11402 is configured with an imaging element. The imaging element constituting the imaging unit 11402 may be one element (a so-called single plate type) or a plurality of elements (a so-called multi-plate type). When the imaging unit 11402 is configured as a multi-plate type, for example, image signals corresponding to RGB are generated by the imaging elements, and a color image may be obtained by synthesizing the image signals. Alternatively, the imaging unit 11402 may be configured to include a pair of imaging elements for acquiring image signals for the right eye and the left eye corresponding to three-dimensional (3D) display. The provision of 3D display allows the operator 11131 to determine the depth of biological tissues in the surgical site with higher accuracy. When the imaging unit 11402 is configured in a multi-plate type, a plurality of systems of lens units 11401 may be provided in correspondence to the image sensors.

The imaging unit 11402 need not necessarily be provided in the camera head 11102. For example, the imaging unit 11402 may be provided immediately after the objective lens inside the lens barrel 11101.

The drive unit 11403 is configured by an actuator and the zoom lens and the focus lens of the lens unit 11401 are moved by a predetermined distance along an optical axis under the control of the camera head control unit 11405. Accordingly, the magnification and focus of the image captured by the imaging unit 11402 can be adjusted appropriately.

The communication unit 11404 is configured using a communication device for transmitting and receiving various types of information to and from the CCU 11201. The communication unit 11404 transmits the image signal obtained from the imaging unit 11402 as RAW data to the CCU 11201 via the transmission cable 11400.

The communication unit 11404 receives a control signal for controlling driving of the camera head 11102 from the CCU 11201 and supplies the camera head control unit 11405 with the control signal. The control signal includes, for example, information regarding imaging conditions such as information indicating designation of a frame rate of a captured image, information indicating designation of an exposure value at the time of imaging, and/or information indicating designation of a magnification and a focus of the captured image.

The imaging conditions, such as the frame rate, the exposure value, the magnification, and the focal point, may be appropriately specified by the user, or may be automatically set by the control unit 11413 of the CCU 11201 on the basis of the acquired image signal. In the latter case, the endoscope 11100 should have a so-called Auto Exposure (AE) function, a so-called Auto Focus (AF) function, and a so-called Auto White Balance (AWB) function.

The camera head control unit 11405 controls driving of the camera head 11102 on the basis of a control signal from the CCU 11201 received via the communication unit 11404.

The communication unit 11411 is constituted of a communication apparatus that transmits and receives various kinds of information to and from the camera head 11102. The communication unit 11411 receives an image signal transmitted via the transmission cable 11400 from the camera head 11102.

The communication unit 11411 transmits the control signal for controlling the driving of the camera head 11102 to the camera head 11102. The image signal or the control signal can be transmitted through electric communication, optical communication, or the like.

The image processing unit 11412 performs various types of image processing on the image signal that is the RAW data transmitted from the camera head 11102.

The control unit 11413 performs various kinds of control on imaging of a surgical site by the endoscope 11100, display of a captured image obtained through imaging of a surgical site, or the like. For example, the control unit 11413 generates a control signal for controlling driving of the camera head 11102.

The control unit 11413 causes the display device 11202 to display a captured image showing a surgical site or the like based on an image signal subjected to the image processing by the image processing unit 11412. In doing so, the control unit 11413 may recognize various objects in the captured image using various image recognition techniques. For example, the control unit 11413 can recognize a surgical instrument such as forceps, a specific biological site, bleeding, mist or the like at the time of use of the energized treatment tool 11112, or the like by detecting a shape, a color, or the like of an edge of an object included in the captured image. When the display device 11202 is caused to display a captured image, the control unit 11413 may superimpose various kinds of surgery support information on an image of the surgical site for display using a recognition result of the captured image. By displaying the surgery support information in a superimposed manner and presenting it to the operator 11131, a burden on the operator 11131 can be reduced, and the operator 11131 can reliably proceed with the surgery.

The transmission cable 11400 that connects the camera head 11102 and the CCU 11201 is an electrical signal cable compatible with communication of electrical signals, an optical fiber compatible with optical communication, or a composite cable of these.

Here, although wired communication is performed using the transmission cable 11400 in the shown example, communication between the camera head 11102 and the CCU 11201 may be performed wirelessly.

An example of the endoscopic surgery system to which the technique according to the present disclosure can be applied has been described above. The technology according to the present disclosure may be applied to the imaging unit 11402 of the camera head 11102 among the configurations described above. Specifically, the light detection device 1 shown in FIG. 4A and the light detection device 1 shown in FIG. 18B can be applied to the imaging unit 11402. By applying the technology according to the present disclosure to the imaging unit 11402, it is possible to obtain an operative site image in which deterioration in color reproducibility is suppressed, thereby enabling the operator to reliably confirm the operative site.

Here, although the endoscopic surgery system has been described as an example, the technology according to the present disclosure may be applied to others, for example, a microscopic operation system.

### OTHER EMBODIMENTS

As described above, the present technology has been described using the first to third embodiments, but the statements and drawings that form part of the present disclosure should not be understood as limiting the present technology. Various alternative embodiments, examples, and operable techniques will be apparent to those skilled in the art from the present disclosure.

For example, it is also possible to combine the technical ideas described in the first to third embodiments. For example, various combinations are possible in accordance with the respective technical ideas, such as applying the characteristics of Modified Example 3 of the first embodiment to the second embodiment and its modified examples.

The present technology can be applied to all light detection devices including not only the solid-state imaging device as the image sensor described above but also a distance measuring sensor that measures distance, also referred to as a ToF (Time of Flight) sensor. The distance measuring sensor is a sensor that emits irradiation light to an object, detects reflective light acquired by reflecting the irradiation light on the surface of the object and has returned, and calculates a distance to the object on the basis of a flight time until the reflective light is received after emission of the irradiation light. As the structure of this distance measurement sensor, the above-described multilayer filter or a structure of a combination of a multilayer filter and an optical element can be adopted.

The light detection device 1 may be a stacking-type CMOS Image Sensor (CIS) in which two or more semiconductor substrates are stacked with overlapping each other. In that case, at least one of the logic circuit 13 and the readout circuit 15 may be provided on a substrate different from the semiconductor substrate on which the photoelectric conversion region 20a is provided among these semiconductor substrates.

For example, the materials listed as constituting the above-mentioned constituent elements may contain additives, impurities, and the like.

In this way, it is of course that the present technology includes various embodiments and the like that are not described herein. Therefore, the technical scope of the present technology is to be determined only by the matters specifying the invention described in the claims that are reasonable from the above description.

Furthermore, the effects described in the present specification are merely exemplary and not intended as limiting, and other advantageous effects may be produced.

Here, the present technology may have the following configurations.

(1)

A light detection device including:
a multilayer filter having a stacked structure in which a high-refractive-index layer and a low-refractive-index layer are alternately stacked, and having a transmission spectrum specific to the stacked structure; and
a semiconductor layer that allows light having passed through the multilayer filter to enter therein and has a plurality of photoelectric conversion regions arranged in a two-dimensional array), wherein
the multilayer filter as a whole is convexly curved toward the semiconductor layer.
   (2)

The light detection device according to (1), further including:
an insulating layer provided between the semiconductor layer and the multilayer filter), wherein a surface of the insulating layer opposite to the semiconductor layer side is a curved surface convexly curved toward the semiconductor layer, and
the multilayer filter is curved along the curved surface of the insulating layer.
   (3)

The light detection device according to (1), wherein
the semiconductor layer is curved together with the multilayer filter.
   (4)

The light detection device according to (3), further including:
a pedestal with one surface convexly curved toward the other surface), wherein
the multilayer filter and the semiconductor layer are fixed to the pedestal along the one surface of the pedestal.
   (5)

The light detection device according to (1), further including:
a glass member whose surface on the semiconductor layer side is convexly curved toward the semiconductor layer), wherein
the multilayer filter is curved along a curved surface of the glass member.
   (6)

The light detection device according to any one of (1) to (5), wherein
the multilayer filter is integrally stacked on the light detection device.
   (7)

The light detection device according to any one of (1) to (6), wherein
the multilayer filter is an infrared-cut filter.
   (8)

An electronic device including:
a light detection device; and
an optical system that forms an image of image light from a subject on the light detection device, the light detection device including:
a multilayer filter having a stacked structure in which a high-refractive-index layer and a low-refractive-index layer are alternately stacked, and having a transmission spectrum specific to the stacked structure; and
a semiconductor layer that allows light having passed through the multilayer filter to enter therein and has a plurality of photoelectric conversion regions arranged in a two-dimensional array), wherein
the multilayer filter as a whole is convexly curved toward the semiconductor layer.
   (9)

The electronic device according to (8), wherein
the multilayer filter is provided only in the light detection device.
   (10)

A light detection device including:
an optical element having a plurality of structures arranged at intervals in a width direction in plan view;
a multilayer filter that allows light having passed through the optical element to enter therein, has a stacked structure in which a high-refractive-index layer and a low-refractive-index layer are alternately stacked, and has a transmission spectrum specific to the stacked structure; and
a semiconductor layer having a light-receiving region formed by arranging a plurality of photoelectric conversion regions in a two-dimensional array on which light having passed through the multilayer filter can be incident), wherein
the optical element is provided, for each photoelectric conversion region, at a position overlapping the photoelectric conversion region in plan view,
in a first optical element that is one of the optical elements arranged so as to overlap a position away from a center of the light-receiving region in plan view, the structures are arranged at least along a direction from a portion of the first optical element near an edge of the light-receiving region to a portion near the center, and
a density of the structures in the first optical element in plan view is higher in the portion of the first optical element near the center of the light-receiving region than in the portion near the edge.
   (11)

The light detection device according to (10), wherein
the density of the structures in the first optical element in plan view gradually increases from the portion of the first optical element near the edge of the light-receiving region to the portion near the center.
   (12)

The light detection device according to (10) or (11), wherein
a widthwise dimension of the structure in plan view gradually increases from the portion of the first optical element near the edge of the light-receiving region to the portion near the center.
   (13)

The light detection device according to any one of (10) to (12), wherein
an arrangement pitch of the structures in plan view gradually decreases from the portion of the first optical element near the edge of the light-receiving region to the portion near the center.
   (14)

The light detection device of any one of (10) to (13), wherein
a second optical element, which is another of the optical elements, is arranged so as to overlap a position closer to the center of the light-receiving region than the first optical element in plan view, and
the density of the structures in the portion of the first optical element near the center of the light-receiving region in plan view is higher than the density of the structures in a portion of the second optical element near the center of the light-receiving region.
   (15)

The light detection device according to (13), wherein
the pitch is less than 400 nm.
   (16)

The light detection device according to any one of (10) to (15), wherein one of the structures included in one of the optical elements is continuous in a direction intersecting a width direction.

(17)

The light detection device according to any one of (10) to (16), wherein
the multilayer filter is integrally stacked on the light detection device.
   (18)

The light detection device according to any one of (10) to (17), wherein
the multilayer filter is an infrared-cut filter.
   (19)

The light detection device according to (18), wherein
the stacked structure of the multilayer filter includes a first stacked structure and a second stacked structure, and
the first stacked structure and the second stacked structure are different in at least one of a film thickness of the high-refractive-index layer and a film thickness of the low-refractive-index layer.
   (20)

An electronic device including:
a light detection device; and
an optical system that forms an image of image light from a subject on the light detection device, the light detection device including:
an optical element having a plurality of structures arranged at intervals in a width direction in plan view;
a multilayer filter that allows light having passed through the optical element to enter therein, has a stacked structure in which a high-refractive-index layer and a low-refractive-index layer are alternately stacked, and has a transmission spectrum specific to the stacked structure; and
a semiconductor layer having a light-receiving region formed by arranging a plurality of photoelectric conversion regions in a two-dimensional array on which light having passed through the multilayer filter can be incident), wherein
the optical element is provided, for each photoelectric conversion region, at a position overlapping the photoelectric conversion region in plan view,
in a first optical element that is one of the optical elements arranged so as to overlap a position away from a center of the light-receiving region in plan view, the structures are arranged at least along a direction from a portion of the first optical element near an edge of the light-receiving region to a portion near the center, and
a density of the structures in the first optical element in plan view is higher in the portion of the first optical element near the center of the light-receiving region than in the portion near the edge.

The scope of the present technology is not limited to the shown and described exemplary embodiments, but includes all embodiments that provide equivalent effects sought after with the present technology. The scope of the present technology is not limited to combinations of characteristics of the invention defined by the claims, but can be defined by any desired combination of specific characteristics among all disclosed characteristics.

### REFERENCE SIGNS LIST

1 Light detection device
2 Semiconductor chip
2A Pixel region
2B Peripheral region
3 Pixel
4 Vertical drive circuit
5 Column signal processing circuit
6 Horizontal drive circuit
7 Output circuit
8 Control circuit
10 Pixel drive line
11 Vertical signal line
12 Horizontal signal line
13 Logic circuit
14 Bonding pad
15 Readout circuit
20 Semiconductor layer
20a Photoelectric conversion region
20b Isolation region
20C Light-receiving region
22 Photoelectric conversion unit
30 Wiring layer
40 Support substrate
50 Light-receiving-surface-side stacked body
53 Color filter
54 On-chip lens
55 Anti-reflection film
56 Planarization film
56a Protective film
57 Light-blocking film
58 Insulating layer
59 Adhesive layer
60, 60A, 60B, 60C Multilayer filter
61 High-refractive-index layer
62 Low-refractive-index layer
70 Optical element layer
71, 71A, 71B Optical element
72, 72A, 72B Structure
100 Electronic device
101 Solid-state imaging apparatus
102 Optical lens (optical system)
103 Shutter device
104 Drive circuit
105 Signal processing circuit
106 Incident light
D, D1 Sealing glass

What is claimed is:

1. A light detection device, comprising:
a multilayer filter having a stacked structure in which a high-refractive-index layer and a low-refractive-index layer are alternately stacked, and having a transmission spectrum specific to the stacked structure; and
a semiconductor layer that allows light having passed through the multilayer filter to enter therein and has a plurality of photoelectric conversion regions arranged in a two-dimensional array, wherein
the multilayer filter as a whole is convexly curved toward the semiconductor layer.

2. The light detection device according to claim 1, further comprising:
an insulating layer provided between the semiconductor layer and the multilayer filter, wherein
a surface of the insulating layer opposite to the semiconductor layer side is a curved surface convexly curved toward the semiconductor layer, and
the multilayer filter is curved along the curved surface of the insulating layer.

3. The light detection device according to claim 1, wherein
the semiconductor layer is curved together with the multilayer filter.

4. The light detection device according to claim 3, further comprising:
a pedestal with one surface convexly curved toward the other surface, wherein
the multilayer filter and the semiconductor layer are fixed to the pedestal along the one surface of the pedestal.

5. The light detection device according to claim 1, further comprising:
a glass member whose surface on the semiconductor layer side is convexly curved toward the semiconductor layer, wherein
the multilayer filter is curved along a curved surface of the glass member.

6. The light detection device according to claim 1, wherein
the multilayer filter is integrally stacked on the light detection device.

7. The light detection device according to claim 1, wherein
the multilayer filter is an infrared-cut filter.

8. An electronic device, comprising:
a light detection device; and
an optical system that forms an image of image light from a subject on the light detection device,
the light detection device comprising:
a multilayer filter having a stacked structure in which a high-refractive-index layer and a low-refractive-index layer are alternately stacked, and having a transmission spectrum specific to the stacked structure; and
a semiconductor layer that allows light having passed through the multilayer filter to enter therein and has a plurality of photoelectric conversion regions arranged in a two-dimensional array, wherein
the multilayer filter as a whole is convexly curved toward the semiconductor layer.

9. The electronic device according to claim 8, wherein the multilayer filter is provided only in the light detection device.

10. A light detection device, comprising:
an optical element having a plurality of structures arranged at intervals in a width direction in plan view;
a multilayer filter that allows light having passed through the optical element to enter therein, has a stacked structure in which a high-refractive-index layer and a low-refractive-index layer are alternately stacked, and has a transmission spectrum specific to the stacked structure; and
a semiconductor layer having a light-receiving region formed by arranging a plurality of photoelectric conversion regions in a two-dimensional array on which light having passed through the multilayer filter can be incident, wherein
the optical element is provided, for each photoelectric conversion region, at a position overlapping the photoelectric conversion region in plan view,
in a first optical element that is one of the optical elements arranged so as to overlap a position away from a center of the light-receiving region in plan view, the structures are arranged at least along a direction from a portion of the first optical element near an edge of the light-receiving region to a portion near the center, and
a density of the structures in the first optical element in plan view is higher in the portion of the first optical element near the center of the light-receiving region than in the portion near the edge.

11. The light detection device according to claim 10, wherein
the density of the structures in the first optical element in plan view gradually increases from the portion of the first optical element near the edge of the light-receiving region to the portion near the center.

12. The light detection device according to claim 10, wherein
a widthwise dimension of the structure in plan view gradually increases from the portion of the first optical element near the edge of the light-receiving region to the portion near the center.

13. The light detection device according to claim 10, wherein
an arrangement pitch of the structures in plan view gradually decreases from the portion of the first optical element near the edge of the light-receiving region to the portion near the center.

14. The light detection device of claim 10, wherein
a second optical element, which is another of the optical elements, is arranged so as to overlap a position closer to the center of the light-receiving region than the first optical element in plan view, and
the density of the structures in the portion of the first optical element near the center of the light-receiving region in plan view is higher than the density of the structures in a portion of the second optical element near the center of the light-receiving region.

15. The light detection device according to claim 13, wherein
the pitch is less than 400 nm.

16. The light detection device according to claim 10, wherein one of the structures included in one of the optical elements is continuous in a direction intersecting a width direction.

17. The light detection device according to claim 10, wherein
the multilayer filter is integrally stacked on the light detection device.

18. The light detection device according to claim 10, wherein
the multilayer filter is an infrared-cut filter.

19. The light detection device according to claim 18, wherein
the stacked structure of the multilayer filter includes a first stacked structure and a second stacked structure, and
the first stacked structure and the second stacked structure are different in at least one of a film thickness of the high-refractive-index layer and a film thickness of the low-refractive-index layer.

20. An electronic device, comprising:
a light detection device; and
an optical system that forms an image of image light from a subject on the light detection device,
the light detection device comprising:
an optical element having a plurality of structures arranged at intervals in a width direction in plan view;
a multilayer filter that allows light having passed through the optical element to enter therein, has a stacked structure in which a high-refractive-index layer and a low-refractive-index layer are alternately stacked, and has a transmission spectrum specific to the stacked structure; and
a semiconductor layer having a light-receiving region formed by arranging a plurality of photoelectric conversion regions in a two-dimensional array on which light having passed through the multilayer filter can be incident, wherein
the optical element is provided, for each photoelectric conversion region, at a position overlapping the photoelectric conversion region in plan view,
in a first optical element that is one of the optical elements arranged so as to overlap a position away from a center of the light-receiving region in plan view, the structures are arranged at least along a direction from a portion of the first optical element near an edge of the light-receiving region to a portion near the center, and
a density of the structures in the first optical element in plan view is higher in the portion of the first optical element near the center of the light-receiving region than in the portion near the edge.
